(19) United States
(12) Patent Application Publication
(10) Pub. No.: US 2003/0015707 A1
(43) Pub. Date: Jan. 23, 2003

(54) Integrated radio frequency , optical, photonic, analog and digital functions in a semiconductor structure and method for fabricating semiconductor structure utilizing the formation of a compliant substrate for materials used to form the same

(75) Inventors: Bruce Allen Bosco, Phoenix, AZ (US); Rudy M. Emrick, Gilbert, AZ (US); Steven James Franson, Scottsdale, AZ (US); Nestor Javier Escalera, Gilbert, AZ (US); Bryan K. Farber, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/905,869

(22) Filed: Jul. 17, 2001

(51) Int. Cl. H01L 29/04

(52) U.S. Cl. 257/73

(57) ABSTRACT

High quality epitaxial layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from the silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. Radio frequency, optical, logic and other circuits in both silicon and compound semiconductor materials may be combined and interconnected in a single semiconductor structure.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals and further includes RF, Optical, Photonic, Analog and Digital devices and circuits.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

For example, compound semiconductor devices made of gallium arsenide, indium phosphide, etc., operate at frequencies, low noise levels and efficiencies which are particularly useful in signal processing applications. However, the cost and fragility of these materials has heretofore prevented their integration into complete systems on a single, monolithic device. Further, many applications require control functions such as digital signal processing or more general processing and memory operations. Such functions now best implemented in silicon technology. No monolithic combination of compound semiconductor technology and silicon technology now exists.

Accordingly, a need exists for a semiconductor structure that provides a high quality monocrystalline film or layer over another monocrystalline material and for a process for making such a structure. Further, a need exists for devices employing such a structure to perform high-complexity signal and data processing, in both analog and digital operations and at DC up to radio frequency and optical frequencies.

### BRIEF DESCRIPTION OF THE DRAWINGS

The present invention is illustrated by way of example and not limitation in the accompanying FIG.s, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 21-23 illustrate schematically, in cross-section, the formation of yet another embodiment of a device structure in accordance with the invention.

FIGS. 24, 25 illustrate schematically, in cross section, device structures that can be used in accordance with various embodiments of the invention.

FIGS. 26-30 include illustrations of cross-sectional views of a portion of an integrated circuit that includes a compound semiconductor portion, a bipolar portion, and an MOS portion in accordance with what is shown herein.

FIGS. 31-37 include illustrations of cross-sectional views of a portion of another integrated circuit that includes a semiconductor laser and a MOS transistor in accordance with what is shown herein.

FIG. 38 shows a semiconductor structure illustrating possible radio frequency (RF) and direct current (DC) interconnections in a monolithic integrated circuit.

FIG. 39 shows another embodiment of possible RF and DC interconnections in a monolithic integrated circuit.

FIG. 40 shows another embodiment of possible RF and DC interconnections in a monolithic integrated circuit.

FIG. 41 shows a possible RF interconnections in a monolithic integrated circuit.

FIG. 42 shows a possible optical interconnections in a monolithic integrated circuit.

FIG. 43 shows an embodiment of possible optical, RF and DC interconnections in a monolithic integrated circuit.

FIGS. 44, 45 show a silicon device and associated transmission lines.

FIGS. 46, 47 show a compound semiconductor device and associated transmission lines and control circuit.

FIGS. 48, 49 show a combination of active and passive silicon and compound semiconductor devices integrated in a monolithic integrated circuit.

FIGS. 50, 51 show an integrated transimpedance amplifier.

FIGS. 52, 53 show an integrated phased array driver and phase shifter.

FIGS. 54, 55 show an integrated radio transceiver.

FIGS. 56, 57 show a bi-directional, bi-wavelength optical line amplifier.

FIGS. 58, 59 show a multiple channel transimpedance amplifier.

FIGS. 60, 61 show an integrated optical transceiver.

Skilled artisans will appreciate that elements in the FIG.s are illustrated for simplicity and clarity and have not necessarily been drawn to scale. For example, the dimensions of some of the elements in the FIG.s may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more filly below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed III-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

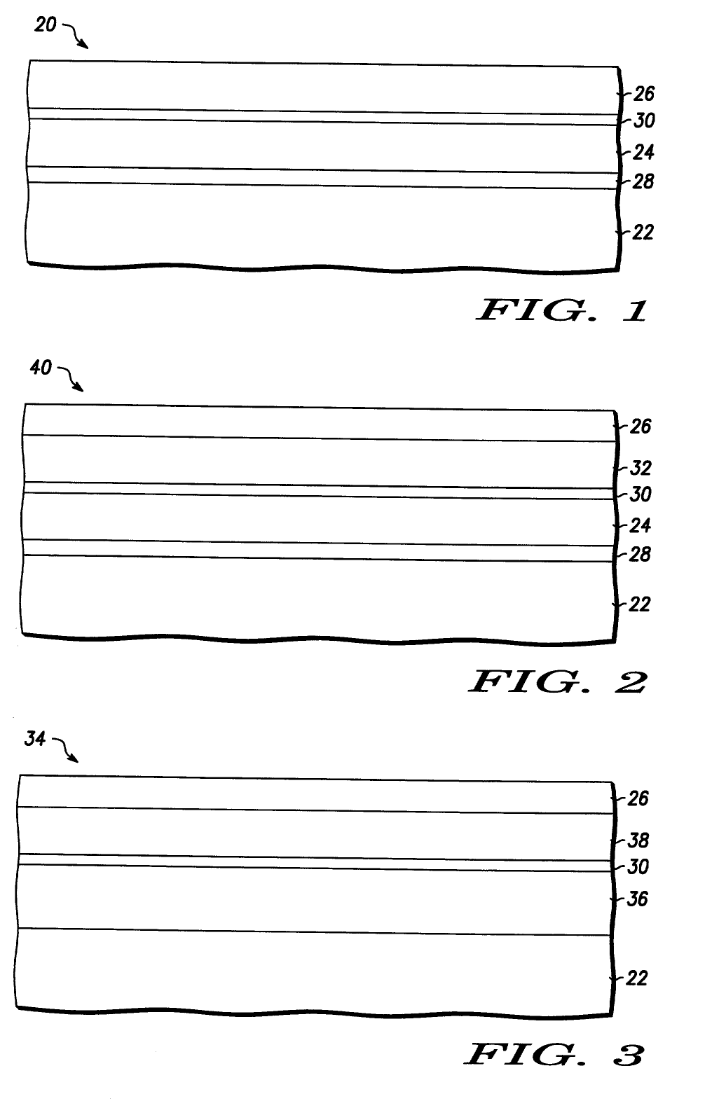

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention.

Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45-degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45-degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAs_{X}P₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes lo GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there 25 is sufficient similarity between the lattice constants to permit the growth of a high quality crystalline layer on the underlying layer.

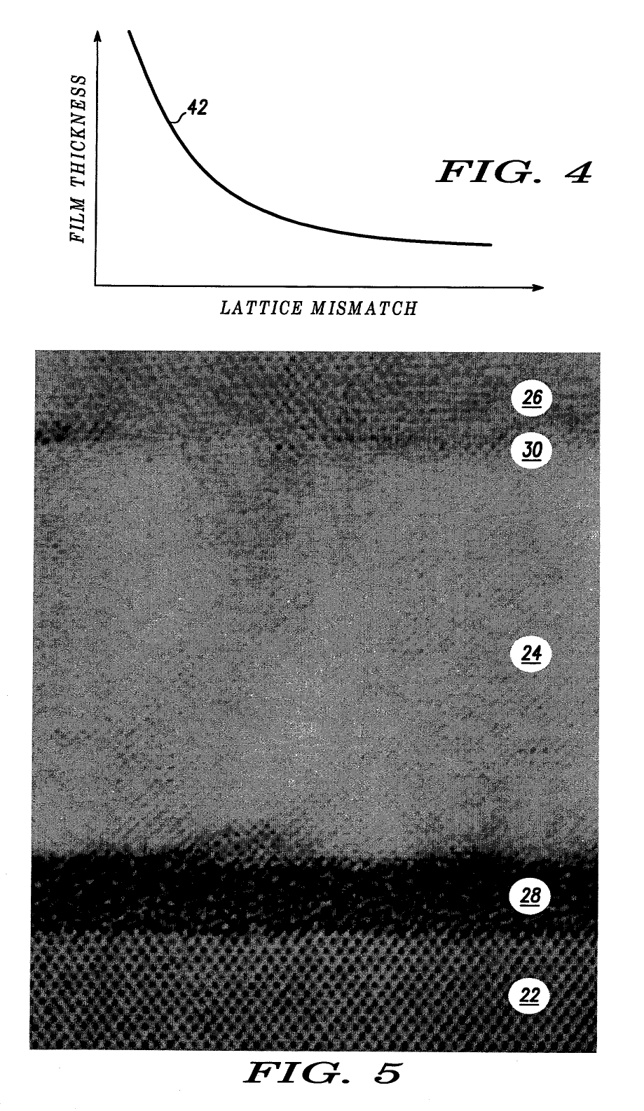

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

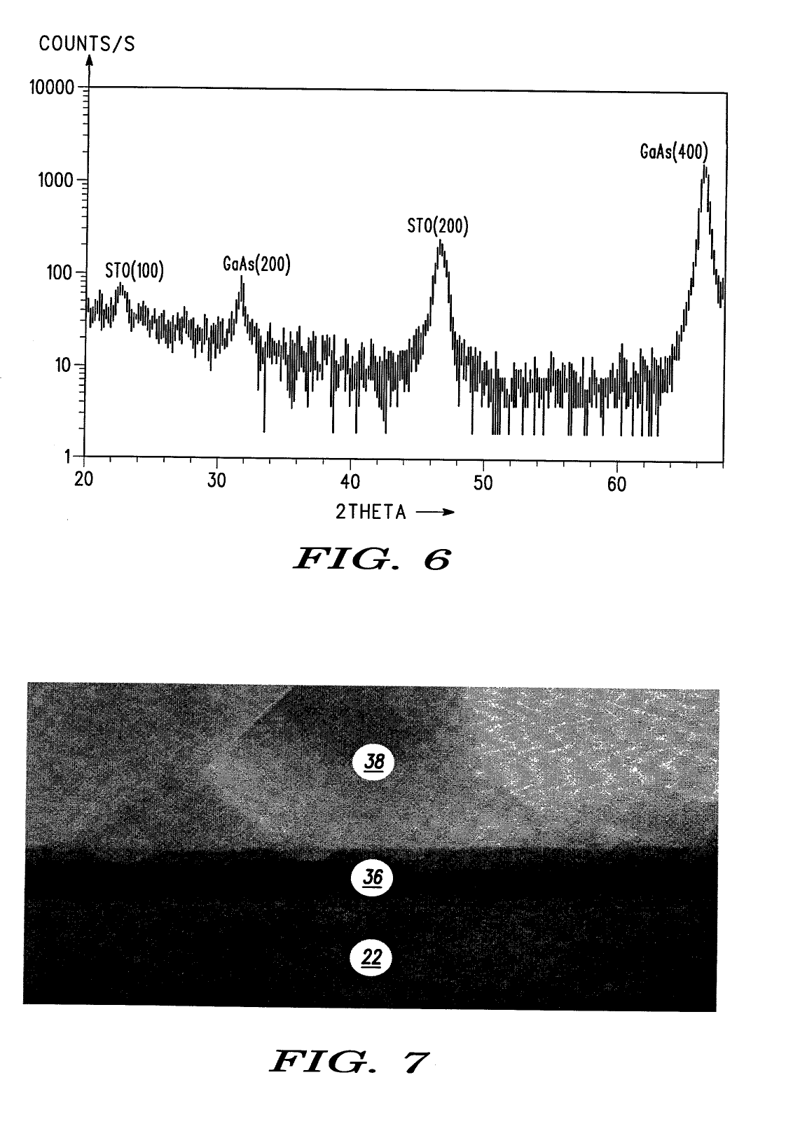

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the Strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for 15 either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

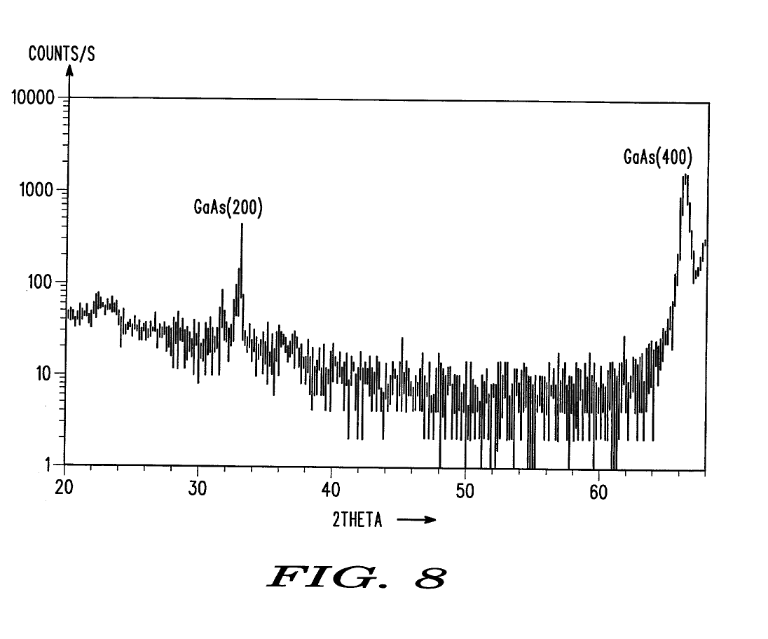

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

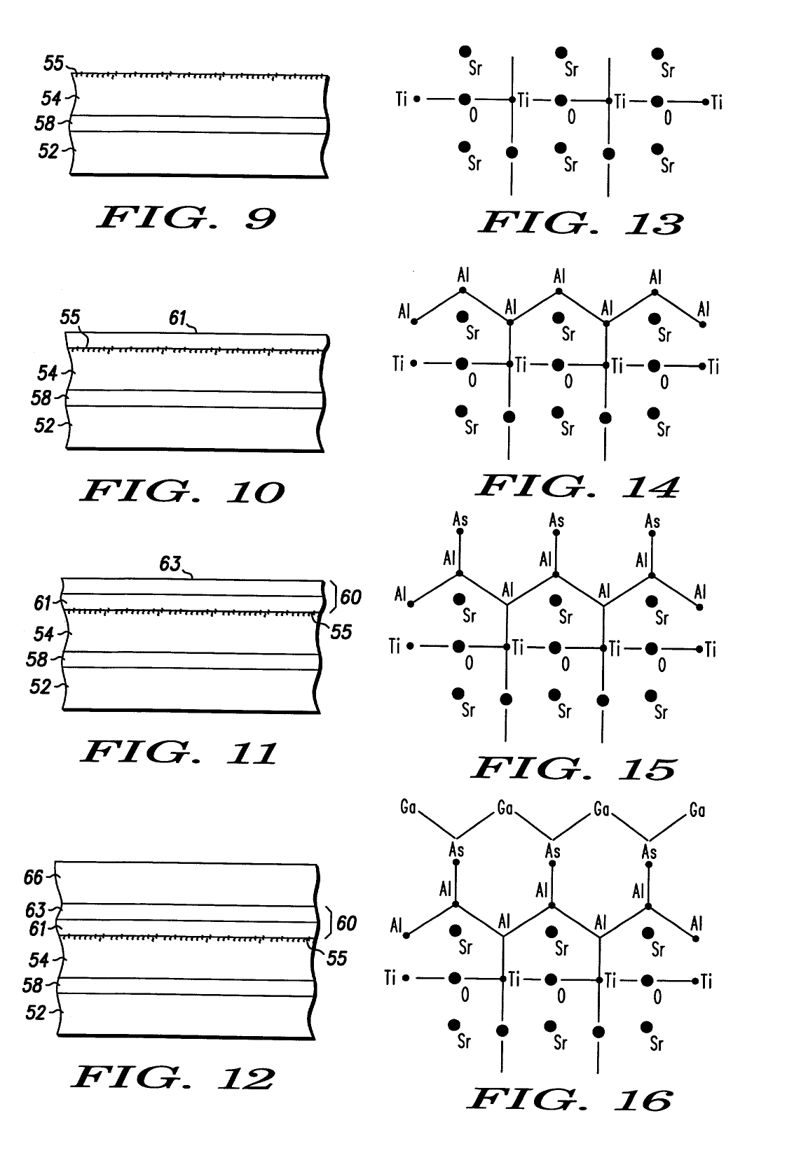

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

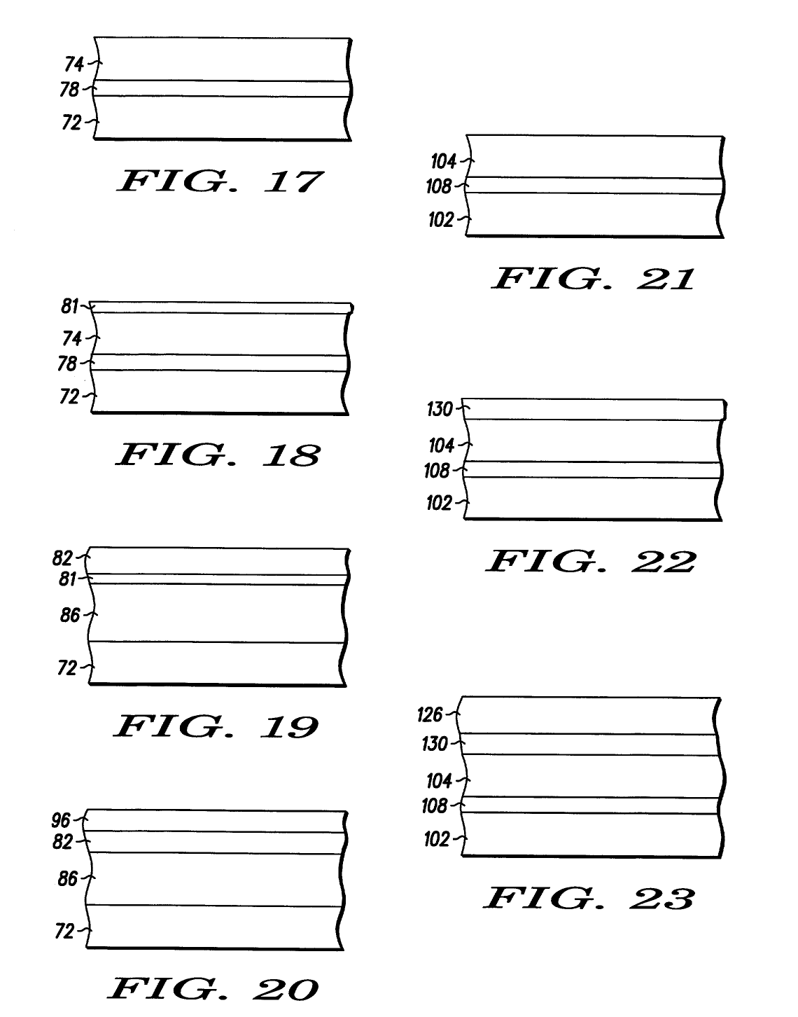

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two-dimensional layer-by-layer growth.

The structure illustrated in FIG. 21 includes a monocrystalline substrate 102, an amorphous interface layer 108 and an accommodating buffer layer 104. Amorphous intermediate layer 108 is grown on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

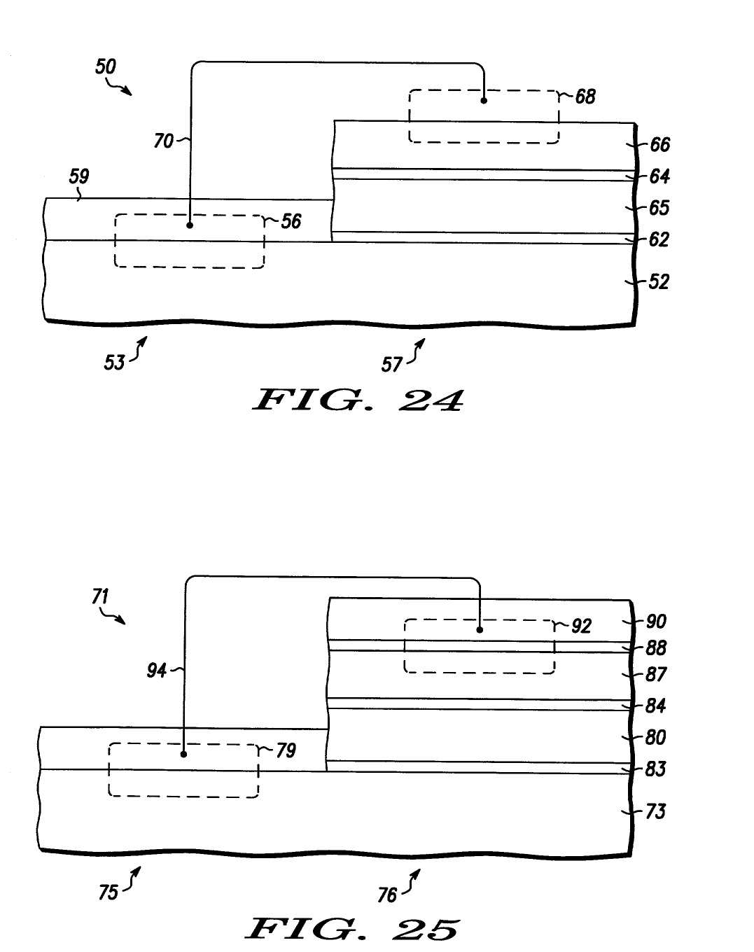

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit conFIG.d to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N³⁰ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺buried region 1102. The doping step converts the dopant type of the lightly p-type epitaxial layer within a section of the bipolar region 1024 to a lightly n-type monocrystalline silicon region. A field isolation region 1106 is then formed between the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N³⁰ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiment may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

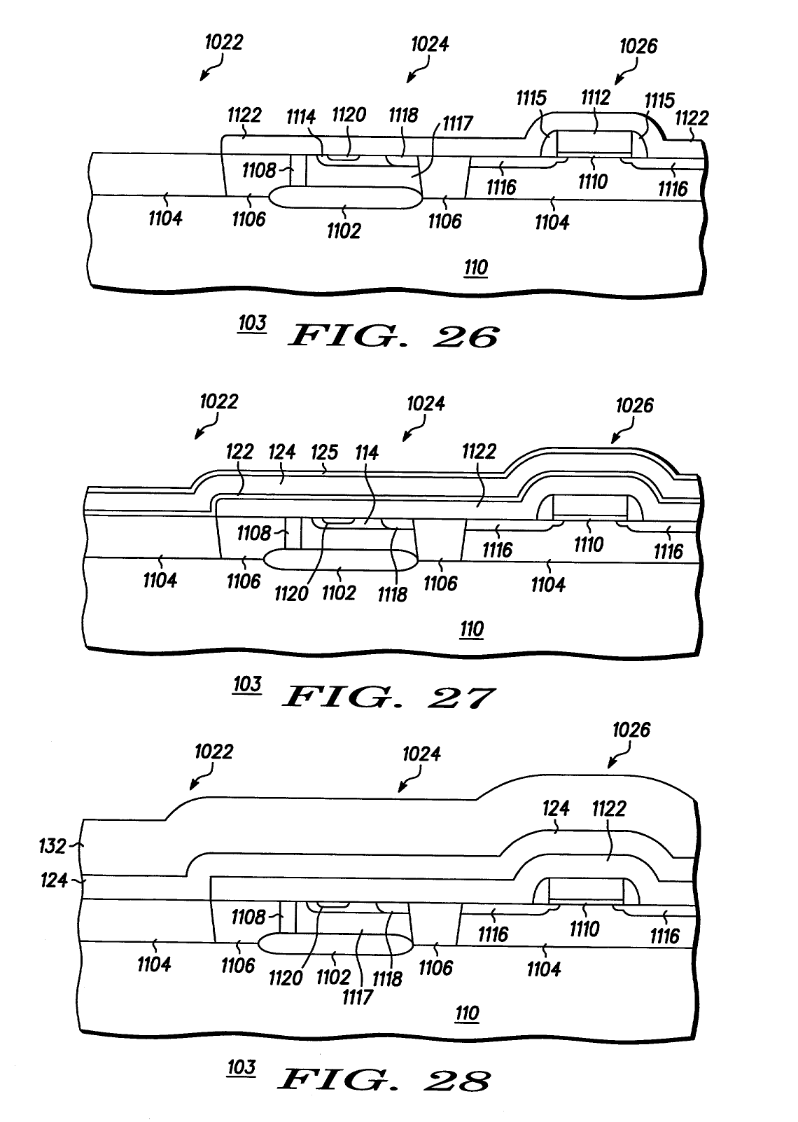

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

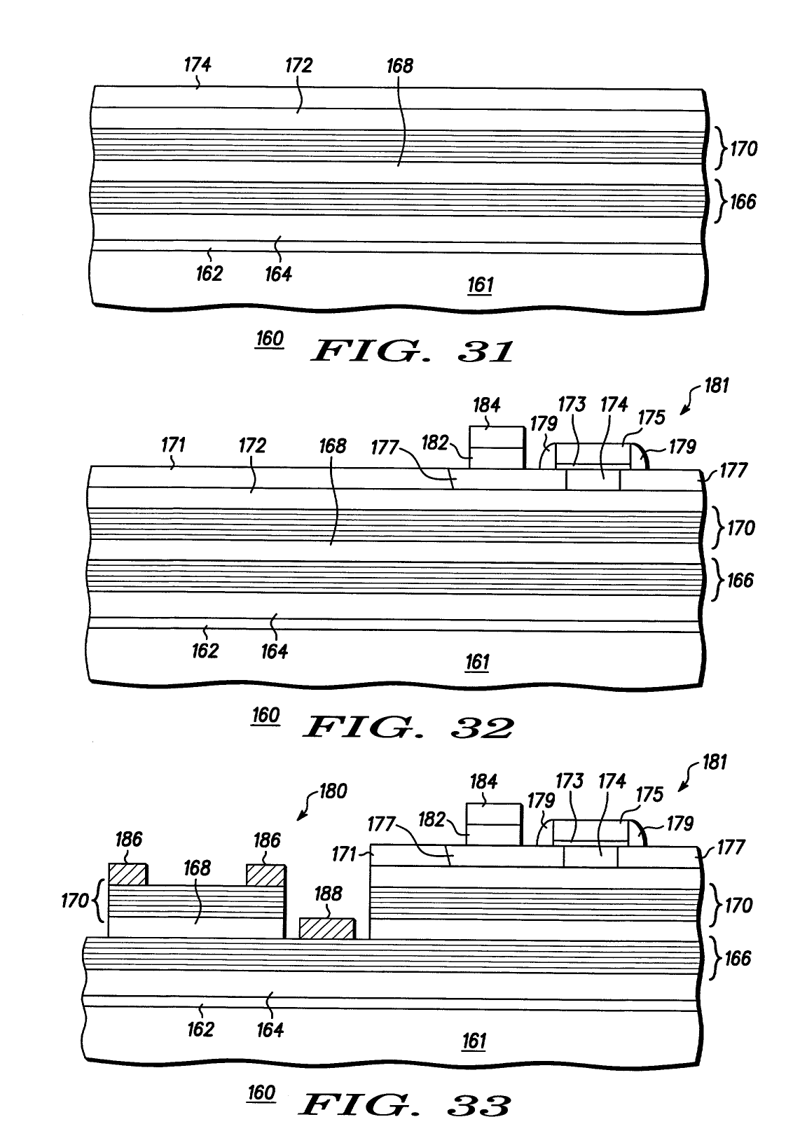

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

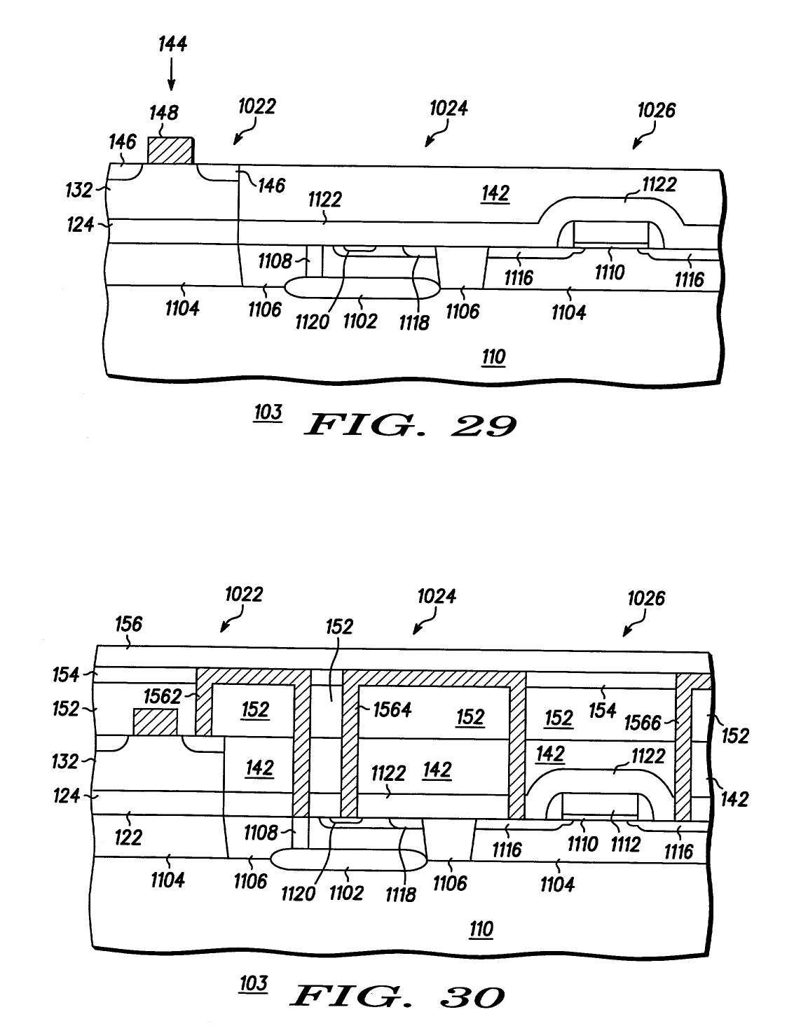

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

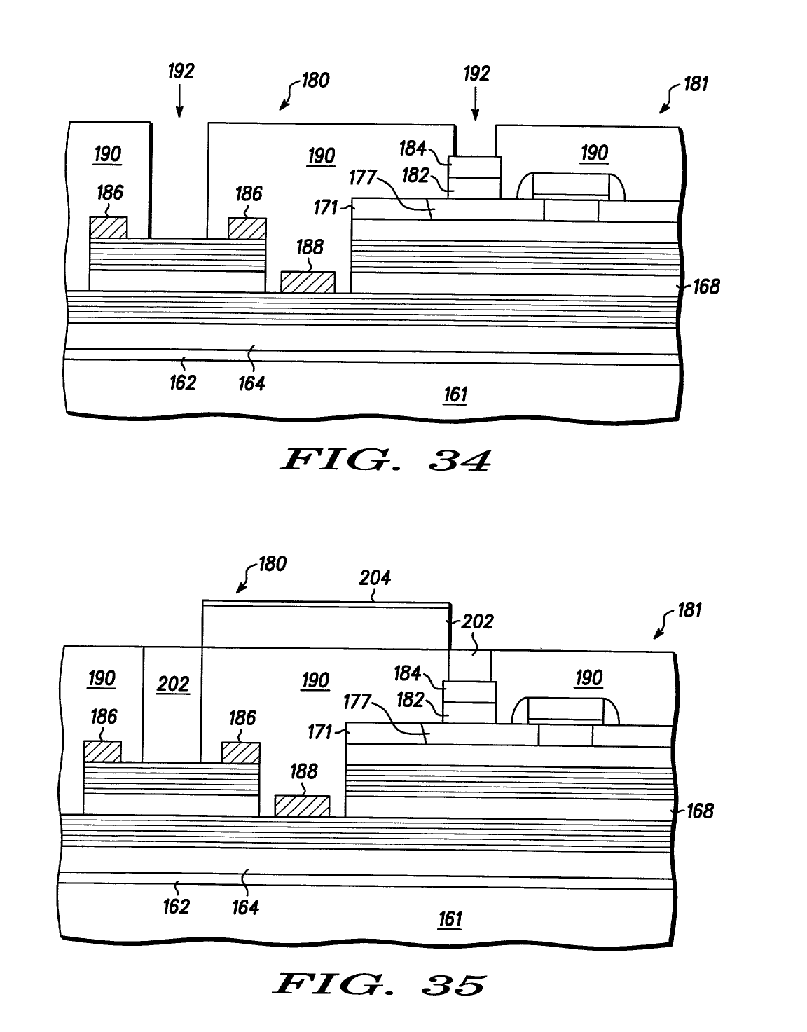

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

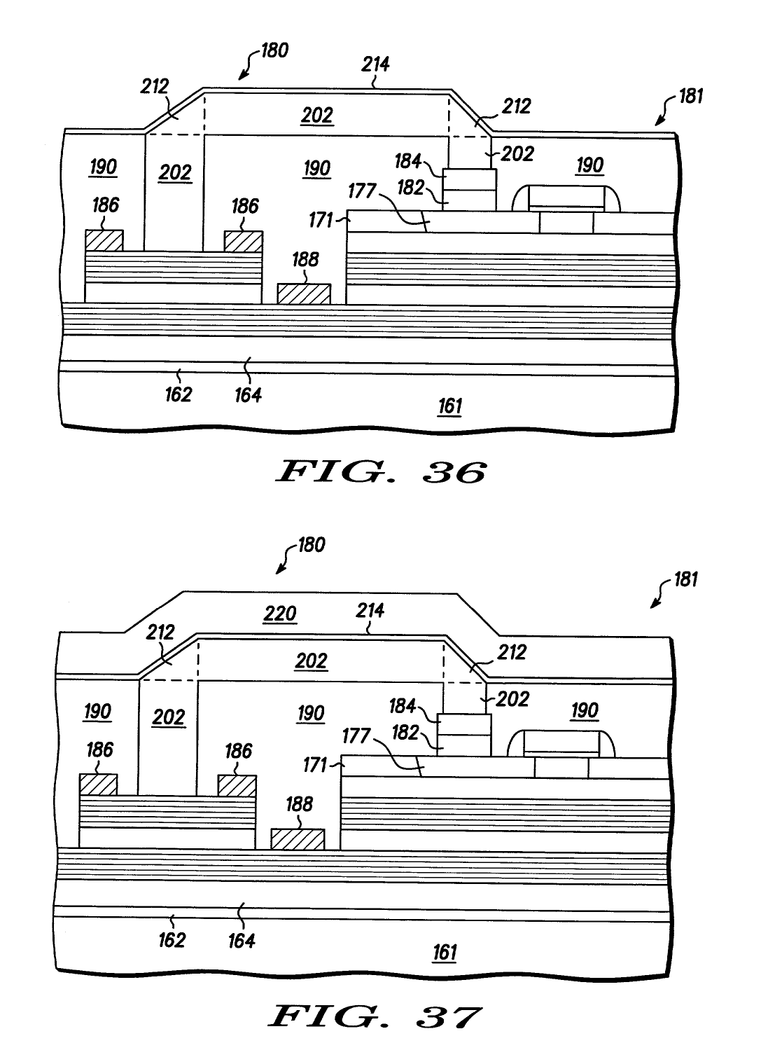

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconFIG.d, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is conFIG.d to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

FIGS. 38-52 show several additional embodiments which may be used in formation of an integrated radio frequency, optical, photonic, analog and digital device in a semiconductor structure. FIG. 38 is a cross-sectional view of a semiconductor structure 3800 illustrating techniques of forming interconnections between silcon and compound semiconductor devices of the semiconductor structure 3800. The semiconductor structure 3800 generally includes a monocrystalline silicon substrate 3802 and a buffer or interfacial layer 3804. In one embodiment, the buffer layer 3804 is formed from an amorphous oxide material overlying the monocrystalline silcon substrate 3802 on a first side 3806 of the semiconductor structure 3800 and a monocrystalline perovskite oxide material overlying the amorphous oxide material. A monocrystalline compound semiconductor material 3808 overlies the buffer layer 3804. On a second side 3810 of the semiconductor structure 3800, a ground plane metallization layer 3812 is formed.

Both silicon and compound semiconductor devices may be formed on the first side 3806 of the semiconductor structure 3800. The embodiment of FIG. 38 shows a first silicon device 3814 and a second silicon device 3816 formed in an epitaxial silicon layer 3818 which has been formed on the silicon substrate 3802. The epitaxial silicon layer 3818 may be formed using any suitable epitaxial process, such as selective epitaxy. The silicon devices 3814, 3816 may be, for example, field effect transistors, heterojunction bipolar transistors, bipolar junction transistors, or passive devices such as resistors and capacitors. Further, in the embodiment of FIG. 38, a compound semiconductor device 3820 and a second compound semiconductor device 3822 are formed in the monocrystalline compound semiconductor material 3808. The devices 3820, 3822 may be, for example, field effect transistors, heterojunction bipolar transistors, or optical devices such as photodiodes or lasers.

FIG. 38 also illustrates interconnections between the silicon devices 3814, 3816 and the compound semiconductor devices 3820, 3822. A first metallized interconnect 3824 electrically couples the compound semiconductor devices 3820, 3822. A second metallized interconnect 3826 electrically couples the compound semiconductor device 3820 and the silicon device 3814. A third metallized interconnect 3828 electrically couples the compound semiconductor device 3822 and the silicon device 3816.

The metallized interconnects 3824, 3826, 3828 may be manufactured using any suitable metallization process. In particular, the chosen process for manufacturing the metallization should provide adequate step coverage, including covering the non-planarity between the compound semiconductor devices 3820, 3822 and the silicon devices 3814, 3816. A combination of metals, such as alloys or a metal sandwich may be used. Preferably, ohmic contacts are formed between the metallization and the semiconductor devices.

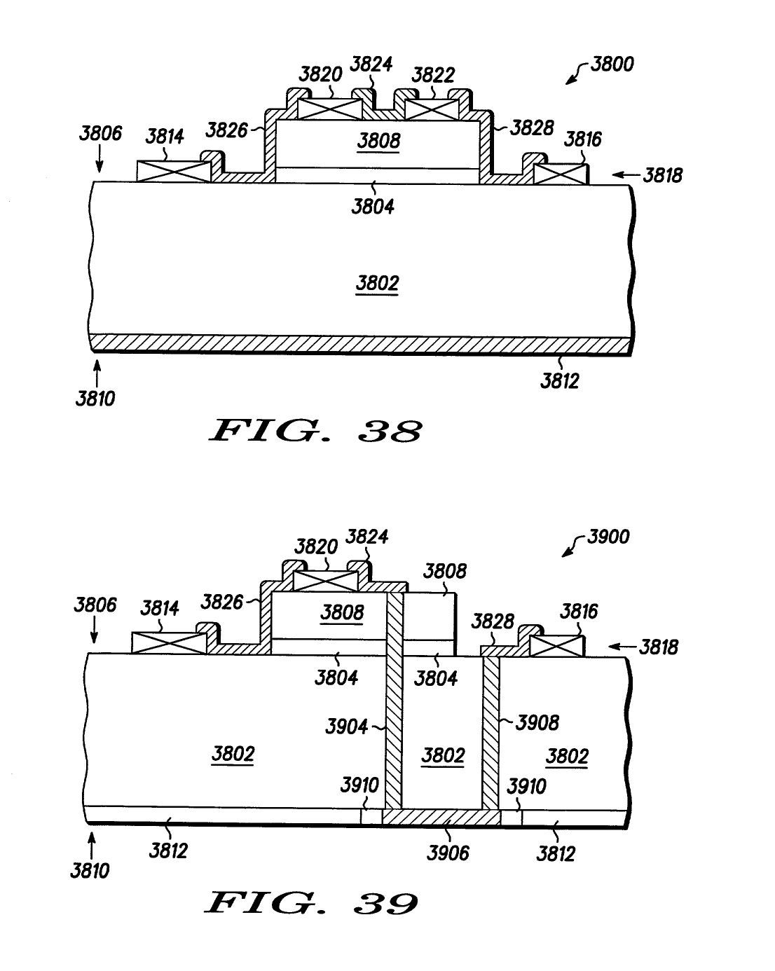

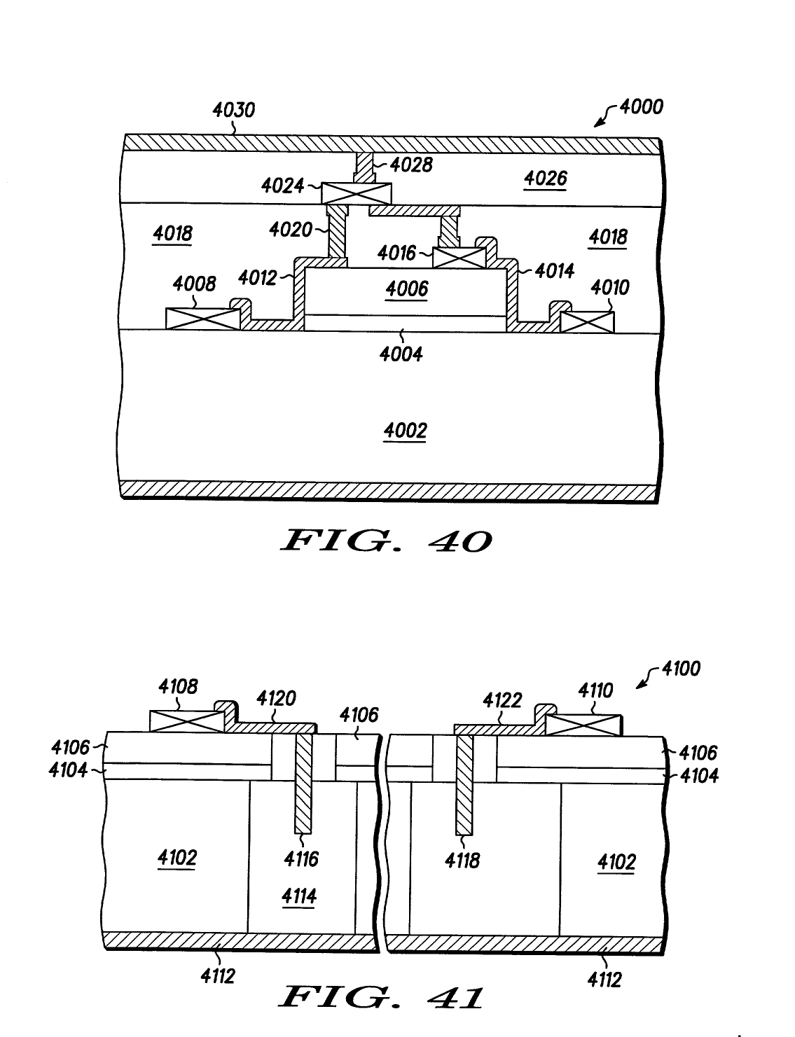

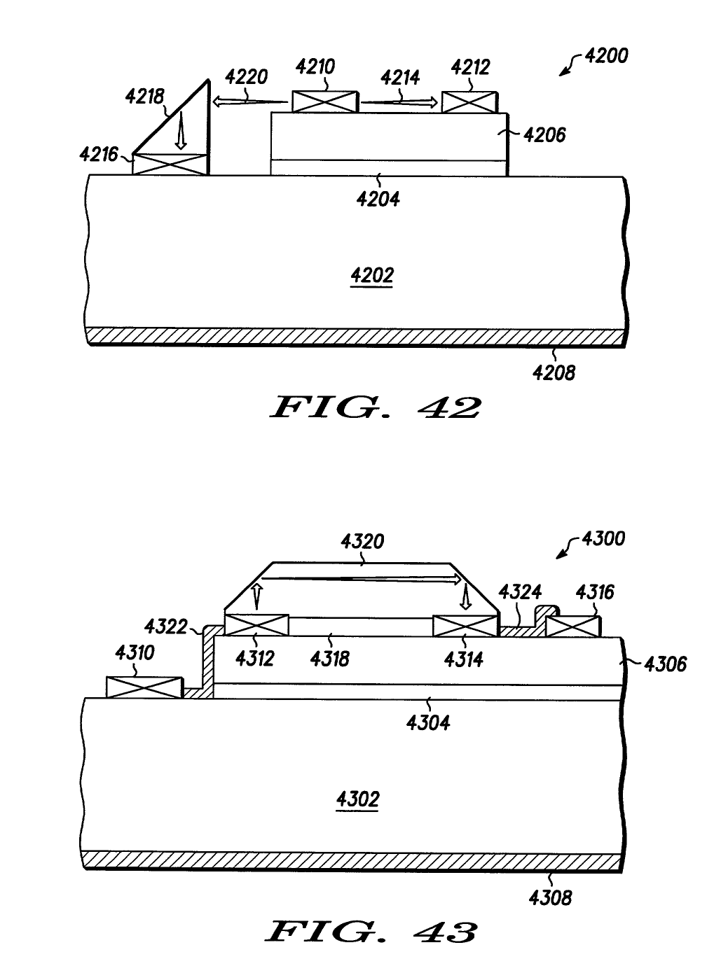

FIG. 39 is a cross-sectional view of a semiconductor structure 3900 showing an alternate embodiment for interconnecting circuits and devices on the semiconductor structure 3900. In the embodiment of FIG. 39, the semiconductor layers including the monocrystalline silicon substrate 3802, the buffer layer 3804 and the monocrystalline compound semiconductor material 3808 are substantially the same as in the embodiment of the FIG. 38. As in FIG. 38, semiconductor devices are formed on the first side 3806 of the semiconductor structure 3900 and ground plane metallization 3812 is formed on the second side 3810 of the semiconductor structure 3900. Silicon devices 3814, 3816 are formed in an epitaxial silicon layer 3818. A compound semiconductor device 3820 is formed in the monocrystalline compound semiconductor material 3808.

For interconnection between the first side 3806 of the semiconductor device 3900 and the second side 3810 of the semiconductor device 3900, a via 3904 extends from metallization on the first side 3806, through the semiconductor structure 3900 to the second side 3810. On the second side 3810, a portion 3906 of the ground plane metallization 3812 is used as interconnect to connect the via 3904 with a second via 3908. The second via 3908 extends back up to the surface on the first side 3806 of the semiconductor structure 3900. In another embodiment, this via 3908 extends all the way to the top surface of the monocrystalline compound semiconductor material 3808 or to another layer, such as an interconnect layer, deposited on top of the monocrystalline compound semiconductor material 3808. In the illustrated embodiment, the vias 3904, 3908 and interconnect 3906 of the second side 3810 permit electrical coupling of compound semiconductor and silicon devices of semiconductor structure 3900. The combination of the vias 3904, 3908 and second side interconnect 3906 forms a crossunder to allow low resistance routing of the interconnect between devices of the semiconductor structure 3900. To electrically isolate the interconnect 3906 from the ground plane metallization 3812, an insulating layer 3910 is formed between the interconnect 3906 and the ground plane metallization 3812.

FIG. 40 is a cross sectional view of a semiconductor structure 4000 illustrating an alternate embodiment for making device interconnections in a semiconductor structure. In the embodiment of FIG. 40, the semiconductor structure 4000 includes a monocrystalline silicon substrate 4002, a buffer layer 4004, including an amorphous oxide material overlying the monocrystalline silicon substrate 4002 and a monocrystalline perovskite oxide material overlying the amorphous oxide material, and a monocrystalline compound semiconductor material 4006 overlying the monocrystalline perovskite oxide material of the buffer layer 4004. Devices 4008, 4010 are formed in a silicon portion of the semiconductor structure 4000. The silicon portion may be the silicon substrate 4002 or may be silicon formed in a layer on the silicon substrate 4002, directly or indirectly, such as an epitaxial silicon layer. Metallized interconnect portions 4012, 4014 electrically couple devices on the surface of the semiconductor structure 4000. Compound semiconductor devices, such as device 4016 are formed on the monocrystalline compound semiconductor material 4006.

In the embodiment of FIG. 40, a low-loss dielectric material 4018 is deposited on the surface of the semiconductor structure 4000 after formation of the silicon devices 4008, 4010 and the compound semiconductor devices 4016, along with the interconnecting metallization. A via 4020 is formed in the dielectric material 4018 and filled with metal or other low-loss conductive material to provide an interconnect between the metallization 4012 and devices 4008, 4010, 4016 and additional devices 4024 formed in a dielectric layer deposited on the surface of the low-loss dielectric layer 4018. The devices 4024 are deposited with an insulating dielectric 4026. Additional vias, such as via 4028, are formed in the dielectric 4026 to form an electrical contact to a ground plane 4030 formed on the top surface of the semiconductor structure 4000.

FIG. 41 is a cross sectional view of a semiconductor structure 4100. The embodiment of FIG. 41 illustrates radio frequency (RF) interconnections made in a semiconductor structure including silicon and compound semiconductor devices. The semiconductor structure 4100 includes a monocrystalline silicon substrate 4102, a buffer layer 4104 and a monocrystalline compound semiconductor material 4106. The buffer layer 4104 may be formed in accordance with any of the embodiments described herein. In one embodiment, the buffer layer 4104 includes an amorphous oxide material overlying the monocrystalline silicon substrate and a monocrystalline perovskite oxide material overlying the amorphous oxide material. The monocrystalline compound semiconductor material 4106 in turn overlies the monocrystalline perovskite oxide material.

A first compound semiconductor device 4108 and a second compound semiconductor device 4110 are fabricated in the monocrystalline compound semiconductor material 4106. The compound semiconductor devices 4108, 4110 may be any suitable devices, such as field effect transistors, heterojunction bipolar transistors (HBT), passive devices such as resistors or capacitors or optical devices such as photodiodes or optical wave guides.

The monocrystalline silicon substrate 4102 is preferably highly conductive silicon. This may be achieved by starting with a conductive silicon substrate or by localized doping of the lightly-doped silicon substrate. Ground plane metallization 4112 is applied to a second or back side of the silicon substrate 4102.

A portion of the silicon substrate 4102 is filled with a dielectric material 4114, forming a wave guide. Vias 4116, 4118 are formed to create electric plane probes for communication with the wave guide. The vias may be formed by any conventional technique, such as by etching a trench or hole in the surface of the semiconductor structure 4100 and filling the trench or hole with metal or a metal compound. Interconnect metallization 4120, 4122 electrically couples the vias 4116, 4118 and the compound semiconductor devices 4108, 4110, respectively. Thus, by means of the wave guide and interconnecting vias 4116, 4118, the compound semiconductor devices 4108, 4110 may communicate information at radio frequencies.

FIG. 42 is a cross sectional view of a semiconductor structure 4200 illustrating an optical interconnection in free space among electronic devices of the semiconductor structure 4200. In particular, the embodiment of FIG. 42 illustrate optical communication between compound semiconductor devices located on a first plane of the semiconductor structure 4200 and a silicon device on a second plane of the semiconductor structure 4200. The semiconductor structure 4200 includes a monocrystalline silicon substrate 4202, a buffer layer 4204 and a monocrystalline compound semiconductor material 4206. These layers may be formed in accordance with any of the embodiments described herein. Ground plane metallization 4208 is applied to the second or back side of the semiconductor structure 4200.

A first compound semiconductor device 4210 is formed in the monocrystalline compound semiconductor material 4206. The first compound semiconductor device 4210 is an optical device, configured to emit light at one or more known frequencies upon electrical stimulation. The appropriate stimulation may be provided by a surrounding circuit, not shown in FIG. 42. Examples of suitable compound semiconductor devices for the device 4210 include a laser diode, a vertical cavity surface emitting laser (VCSEL) or any other suitable optical source.

A second optical compound semiconductor device 4212 is also formed in the monocrystalline compound semiconductor material 4206. The second device 4212 may be any optical device which may respond to emitted light 4214 from the first device 4210. Examples of devices suitable for forming the second device 4212 include a photo detector or photo diode.

A silicon optical device 4216 is formed in a silicon portion of the semiconductor structure 4200. The silicon portion may be the monocrystalline silicon substrate 4202 or may be a silicon layer such as epitaxial silicon formed on the surface of the substrate 4202. The silicon optical device 4216 may be, for example, a solar cell or photo diode or other optical device responsive to light.

A light reflecting device 4218 is formed adjacent to the silicon optical device 4216 to reflect incoming light 4220 from the first optical device 4210. The light reflecting device 4218 deflects the incoming light 4220 from a horizontal plane to a vertical plane, as shown in FIG. 42. The light reflecting device 4218 may be formed using any suitable device, such as a mirror or grating, or, in another embodiment, a micro-electro-mechanical system (MEMS) device could perform this function.

Thus, communication may occur using light emitted from the first compound semiconductor device 4210. Emitted light 4214 is detected by the second compound semiconductor device 4212 which is generally coplanar with the first compound semiconductor device 4210. The emitted light 4214 is conveyed through free space. Since, in the illustrated embodiment, not all devices lie in the same plane, the light reflecting device 4218 permits deflection of emitted light 4220 from the first compound semiconductor device 4210 to a second plane containing the silicon optical device 4216. It is to be understood that any number of mirrors or other devices, such as the light reflecting device 4218, could be used to deflect emitted light from an optical source, such as the device 4210, to an optical receiver, such as the silicon optical device 4216. The reflections may occur among horizontal planes, as is illustrated in FIG. 42 using the light reflecting device 4218, or reflections may occur within a single plane using similarly constructed mirror or grating devices.

FIG. 43 is a cross sectional view of a semiconductor structure 4300 illustrating optical, radio frequency and DC interconnections in a semiconductor structure. In this embodiment, the optical interconnection is guided within an optical wave guide.

The semiconductor structure 4300 includes a monocrystalline silicon substrate 4302, a buffer layer 4304 formed on the monocrystalline silicon substrate 4302 and a monocrystalline compound semiconductor layer 4306 formed on the buffer layer 4304. The buffer layer may be formed in any suitable manner. In one embodiment, an amorphous oxide material overlies the monocrystalline silicon substrate 4302 and a monocrystalline perovskite oxide material overlies the amorphous oxide material to form the buffer layer 4304. The monocrystalline compound semiconductor material 4306 in turn overlies the monocrystalline perovskite oxide material. A ground plane metallization 4308 is applied to the back side of the semiconductor structure 4300.

Active semiconductor devices are formed in the front side, or top surface, of the semiconductor structure 4300. A silicon device 4310 is formed in a silicon portion of the semiconductor device. The silicon portion may be the monocrystalline silicon substrate 4302 or a silicon layer, such as epitaxial silicon, overlying the silicon substrate 4302. Compound semiconductor devices 4312, 4314, 4316 are formed in the monocrystalline compound semiconductor material 4306. In the illustrated embodiment, the device 4312 is an optical device which emits light, such as a laser diode or VCSEL. The device 4314 is an optical device which detects, or responds to, incident light, such as a photo detector or photo diode.

A space between the compound semiconductor devices 4312, 4314 is filled with a dielectric material 4318. Overlying the dielectric layer 4318 and the compound semiconductor devices 4312, 4314 is an optical wave guide 4320. The optical wave guide 4320 may be formed using any suitable technique or material. The optical wave guide 4320 preferably is substantially lossless, reflecting light received from the first compound semiconductor device 4312 and providing substantially all the received light to the second compound semiconductor device 4314. Alternate embodiments could include photonic switch(es), using MEMs incorportated on the silicon layer to direct light to or from one or more of a plurality of interconnected optical wave guides as desired.

Interconnect metallization 4322 is formed to electrically connect the semiconductor device 4310 and the first compound semiconductor device 4312. Similarly, interconnect metallization 4324 is formed to electrically interconnect the second compound semiconductor device 4314 and the third compound semiconductor device 4316. In this way, the optical elements 4312, 4314 are also electrically coupled with an adjacent circuit.

The optical elements 4312, 4314 provide optical communication. The interconnect metallization 4322, 4324 provide electronic communication. The devices in the embodiment of FIG. 43 may perform a variety of functions. For example, the silicon device 4310 may operate as a controlling device such as a modulator. The modulator 4310 controls the operation of the compound semiconductor light emitting device 4312. Light signals received at the light detecting device 4314 are converted to electrical signals. The third compound semiconductor device 4316 may operate as, for example, an amplifier so that electrical signals produced by the light detecting device 4314 are amplified by the amplifier 4316.

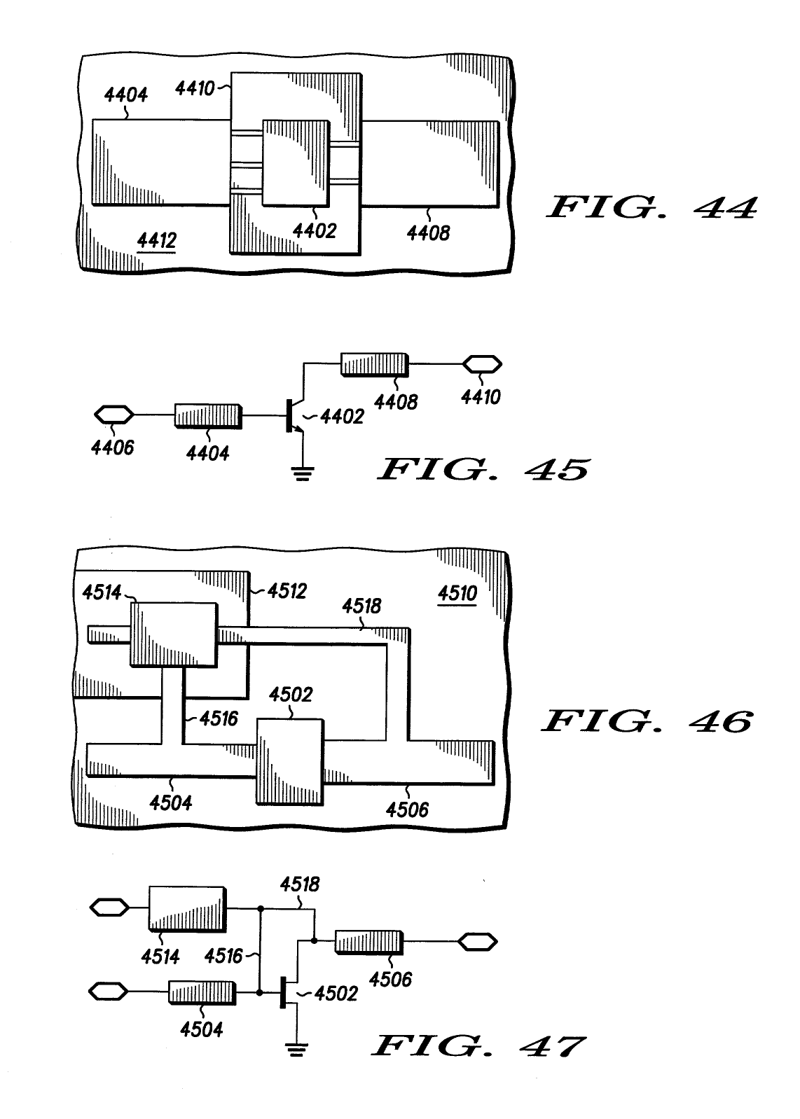

FIGS. 44-49 show in schematic and block diagram form several examples of possible combinations of circuits and components that can be implemented using the novel multiple layer, multi-material technology described herein. FIGS. 44, 45 are a schematic and block diagram view of an active device on a silicon substrate with adjacent input and output transmission lines on a low-loss compound semiconductor layer. The active device in FIGS. 44, 45 is a transistor 4402, such as a bipolar junction transistor or SiGe heterojunction bipolar transistor (HBT). A base of the transistor 4402 is driven through a first transmission line 4404, which is in turn coupled with an input 4406. The input 4406 is configured to receive a suitable input signal, such as a time varying voltage or current signal. The collector of the transistor 4402 is coupled with an output transmission line 4408, which is further coupled with an output 4410.

FIGS. 44, 45 also shows a top view of a portion of a possible circuit layout for the transistor 4402 and transmission lines 4404, 4408. The transistor 4402 is formed in a silicon portion 4410. The transmission lines 4404, 4408 are formed over compound semiconductor material 4412. The devices illustrated in FIGS. 44, 45 may be formed as a monolithic semiconductor structure in accordance with any of the embodiments shown or described herein. In general, a buffer layer is formed on a monocrystalline silicon substrate and a monocrystalline compound semiconductor material is formed overlying the buffer layer. Silicon devices, such as the transistor 4402, may be formed in the silicon substrate material or in locally grown silicon material.

FIGS. 46, 47 illustrate an active compound semiconductor device in conjunction with low-loss transmission lines also formed on a compound semiconductor layer. Control circuitry includes silicon devices formed in an adjacent silicon portion.

The semiconductor structure 4500 includes an active compound semiconductor device 4502, an input transmission line 4504 and an output transmission line 4506. The active device 4502 may be any suitable compound semiconductor device such as a transistor, optical device or otherwise. In the embodiment of FIGS. 46, 47, the active device is a transistor such as a high electron mobility transistor or metal semiconductor field effect transistor. The compound semiconductor device 4502 is formed on a compound semiconductor portion 4510 of the semiconductor structure 4500. Adjacent to the compound semiconductor portion 4510, a silicon portion 4512 contains a control circuit 4514. The silicon control circuit 4514 includes at least, in part, silicon devices such as transistors which implement control functions including data storage to control the circuitry which includes the active device 4502. The silicon portion 4512 may be a portion of the monocrystalline silicon substrate containing the semiconductor structure 4500. Alternatively, the silicon portion 4512 may be a locally grown silicon layer such as epitaxial silicon. A control line 4516 couples the control circuit 4514 and a gate of the active device 4502. Similarly, a control line 4518 couples the drain of the device 4502 and the control circuit 4514.

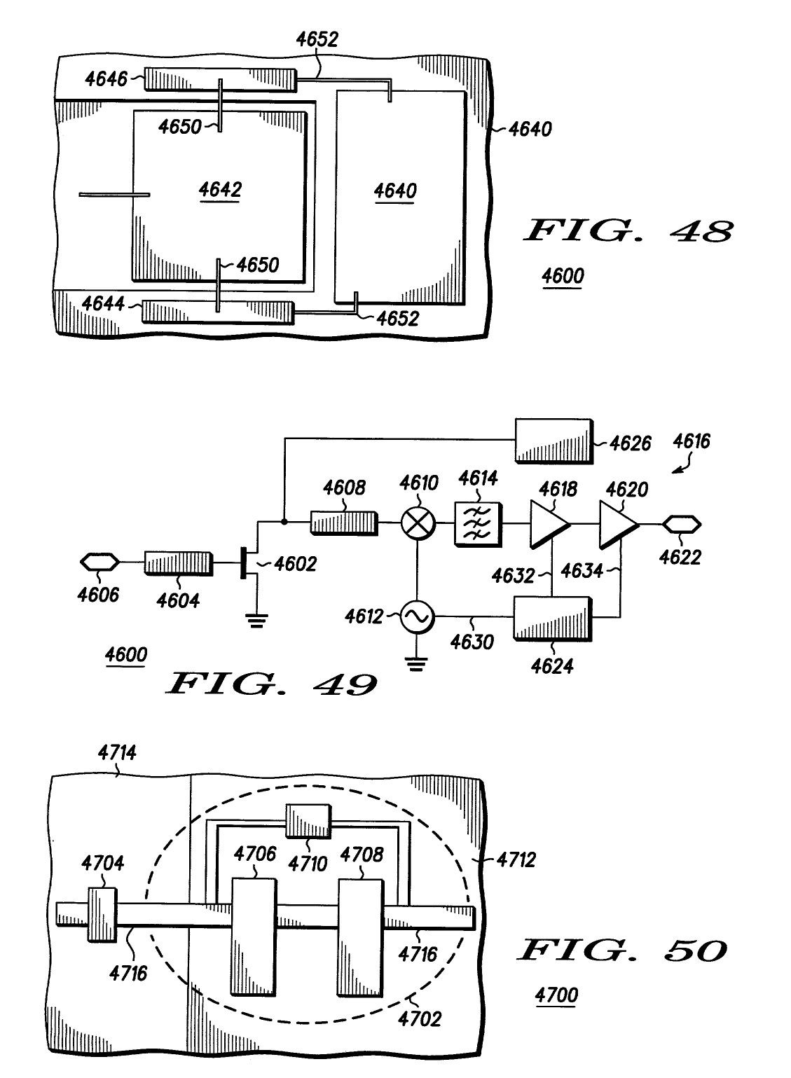

FIGS. 48, 49 illustrate a combination of active and passive devices on both compound semiconductor layers and silicon in a common monolithic semiconductor structure, such as an integrated circuit. Complex control functions reside on a silicon portion of the semiconductor structure 4600. The illustrated embodiment forms an integrated down converter.

The semiconductor structure 4600 includes an active device 4602 formed on a compound semiconductor portion of the semiconductor structure. The active device 4602 in the illustrated embodiment is a compound semiconductor transistor. The 15 transistor 4602 is fed at its gate by a transmission line 4604 coupled to an input 4606 of the circuit. At the drain of the transistor 4602, a transmission line 4608 couples to a mixer 4610. The mixer 4610 has two inputs. The first input is coupled with the transmission line 4608. The second input is coupled to an oscillator 4612. The output of the mixer 4610 is coupled to a filter 4614. The output of the filter 4614 is coupled to an amplification circuit 4616, which includes a first amplifier 4618 and a second amplifier 4620. The amplifier 4620 drives an output signal at an output 4622 of the circuit. Control functions are provided by a first silicon control circuit 4624 and a second silicon control circuit 4626.

The interconnections of the circuit of the semiconductor structure 4600 are illustrated in FIGS. 48, 49. The first control circuit 4624 controls the oscillator 4612 via a control line 4630. The control circuit 4624 controls the amplifier 4618 via a control line 4632 and controls the amplifier 4620 via a control line 4634. The second control circuit 4626 controls the device 4602 via a control line 4636. Some of the control lines 4630, 4632, 4634, 4636 are used for sensing signals at the controlled device, for applying a bias signal to the controlled device, or for a combination of these. The control lines may include several separate wires forming the control line.

FIGS. 48, 49 also illustrate one example of partitioning of the circuitry among a silicon portion 4640 and a compound semiconductor portion 4642 of the semiconductor structure. Compound semiconductor devices, such as the active device 4602, the mixer 4610 and the oscillator 4612 are combined in the compound semiconductor portion 4642. Other circuitry including the control circuits 4624, 4626, the filter 4614, and the amplifier 4618, 4620 are formed on the silicon portion 4640 of the semiconductor structure 4600. The silicon portion 4640 may include the silicon substrate on which the semiconductor structure 4600 is formed, a silicon layer formed on the silicon substrate, such as epitaxial silicon, or a combination of these.

Further, as is shown in FIGS. 48, 49, the silicon portion 4640 may be segmented into other silicon portions, such as silicon portion 4644 and silicon portion 4646. Such segmenting allows the appropriate control or operating circuitry to be placed close to the associated compound semiconductor circuitry of the compound semiconductor portion 4642. Control lines 4650 extend from the silicon portion 4644, 4646 to the compound semiconductor portion 4642 to provide the control operation. Further, control lines 4652 extend from silicon portions 4644, 4646 to other silicon portions 4640 to provide communication between the silicon portions.

The control functions provided by the silicon portion include biasing, temperature compensation, control for the oscillator 4612 if the oscillator 4612 is, for example, a voltage controlled oscillator. In such case, the control operation could include implementation of a phase-locked loop. Further control functions include a look-up table for the filter circuit 4616.

In alternative embodiments, partitioning of the circuitry may be accomplished in alternative manners. For example, the filter 4614 may be implemented using compound semiconductor devices of the compound semiconductor portion 4642. In another example, the mixer 4610 may be implemented using a combination of compound semiconductor devices of the compound semiconductor portion 4642 and silicon devices of the silicon portion 4640. Appropriate metal interconnections may be made among the two portions 4640, 4642 to achieve the necessary functionality. Other combinations are possible.

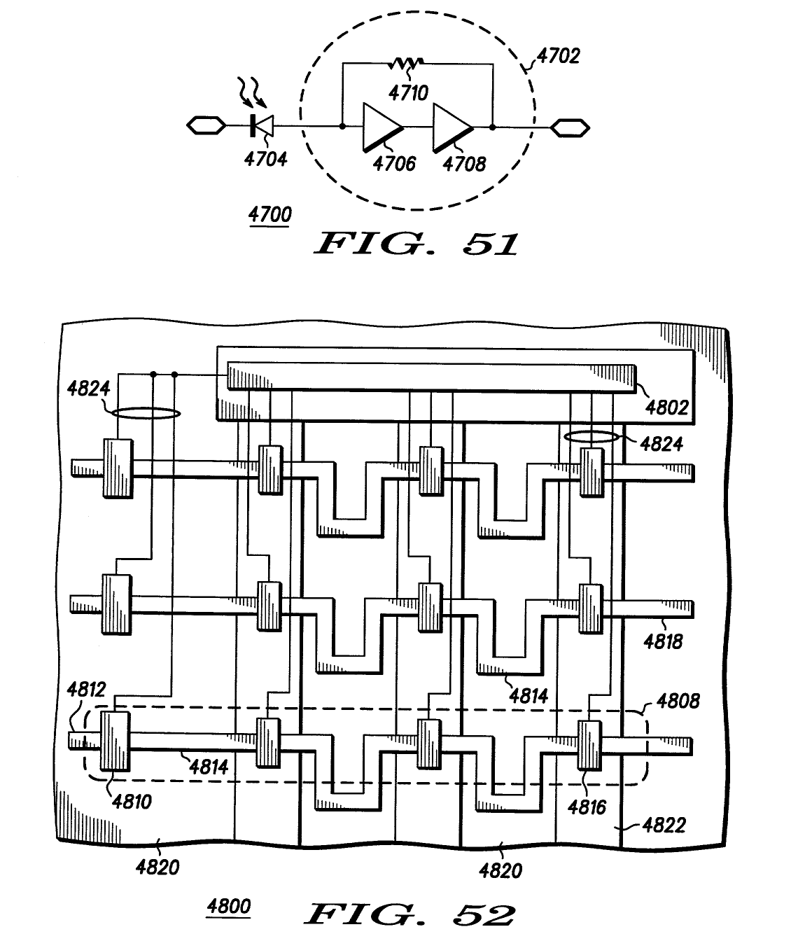

FIGS. 50, 51 illustrate a semiconductor structure 4700 including an integrated transimpedance amplifier 4702. In the embodiment of FIG. 50, 51, the semiconductor structure is a generic, two-stage transimpedance amplifier with resistive feedback. The semiconductor structure 4700 includes a photodiode 4704 and the transimpedance amplifier 4702. The transimpedance amplifier 4702 includes a first amplifier 4706 a second amplifier 4708 and a feedback resistor 4710.

FIGS. 50, 51 also show a top view of one embodiment of a circuit design or layout showing partitioning of the components of the transimpedance amplifier 4700 among a silicon portion 4712 and a compound semi-conductor portion 4714 of semiconductor structure at 4700. The semiconductor structure 4700 is preferably formed in accordance with any of the embodiments described herein and includes in one embodiment a monocrystaline silicon substrate, an amorphous oxide material overlying the monocrystaline silicon substrate and a monocrystaline perovskite oxide material overlying the amorphous oxide material. The amorphous oxide material and the monocrystaline perovskite oxide material together form a buffer layer. A monocrystaline compound semiconductor material overlies the monocrystaline perovskite oxide material of the buffer layer. The compound semiconductor portion 4714 is formed in the monocrystaline compound semiconductor material. The silicon portion 4712 is formed in the monocrystaline silicon substrate or in a silicon layer such as epitaxial silicon or epi SiGe formed on top of the monocrystaline silicon substrate, or both.

In the embodiment of FIGS. 50, 51, the photodiode 4704 is formed in the compound semiconductor portion 4714. A transmission line 4716 formed on the compound semiconductor material 4714 couples the photodiode 4704 with the transimpedance amplifier 4702. The photodiode 4704 receives incident light and produces an electronic signal which is provided to the transimpedance amplifier 4702.

The amplifiers 4706, 4708 and the resister 4710 are formed in the silicon portion 4712 of the semiconductor structure 4700 in the illustrated embodiment. In the embodiment, the active devices such as transistors which form the amplifiers 4706, 4708 are implemented on the silicon substrate. One preferred embodiment would include heterojunction bipolar transistors. This could be either on the silicon substrate, or on a SiGe epitaxial layer-preferred. Alternatively, the amplifiers could be formed of silicon bipolar junction transistors or even metal-oxide-semiconductor field effect transistors (MOS FETS).

The feedback resister 4710 is formed by implanting a region of the silicon portion 4712 to form a resistive component. Alternatively, a resistive component may be formed by depositing and doping a film such as polysilicon on the surface of the semiconductor structure 4700. The output signal from the amplifier 4702 is conveyed on a transmission line 4716 on the silicon portion 4712.

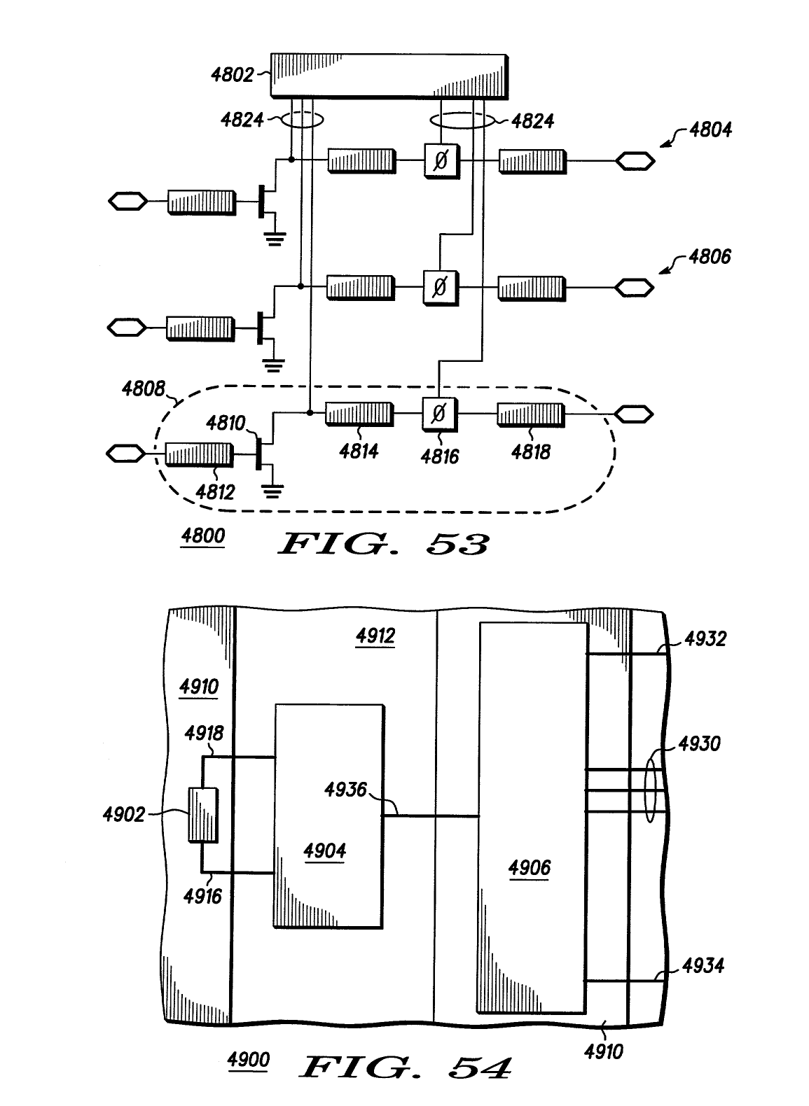

FIGS. 52, 53 illustrate a semiconductor structure forming an integrated phased array driver 4800. The semiconductor structure 4800 includes a control circuit 4802 and a plurality of phased-array channels 4804, 4806, 4808. Preferably each of the channels 4804, 4806, 4808 is identical and processes a similar signal, although there may be variations among the channels. There may be embodiments in which the phases are different, for example, in which a fixed amount of phase offset between channels is incorporated.

The illustrated embodiment includes three phased-array channels. It is to be understood that the number of channels may be varied to accommodate particular needs of a particular design. The structure and operation of channel 4808 will be described. The structure and operation of the other channels 4804, 4806 will be similar. The phased-array channel 4808 includes an active transistor 4810, an input transmission line 4812, a transmission line 4814, a phase shift element 4816 and an output transmission line 4818.

FIGS. 52, 53 illustrate a top view of one embodiment of a circuit layout of the phased-array driver 4800. In FIGS. 52, 53, the semiconductor structure 4800 includes a compound semiconductor portion 4820 and a silicon portion 4822. The semiconductor structure 4800 may be manufactured in accordance with any of the embodiments illustrated herein. In one embodiment, the semiconductor structure 4800 includes a monocrystalline silicon substrate and a buffer layer overlying the monocrystalline silicon substrate. The buffer layer includes in one embodiment an amorphous oxide material overlying the monocrystaline silicon substrate and a monocrystaline perovskite oxide material overlying the amorphous oxide material. A monocrystaline compound semiconductor material overlies the monocrystaline perovskite oxide material. The compound semiconductor portion 4820 is formed from the monocrystaline compound semiconductor material. The silicon portion 4822 is formed from the monocrystaline substrate or a silicon layer, such as empitaxial silicon formed on the monocrystaline silicon substrate. As can be seen in FIGS. 52, 53, only the phase shift elements 4816 are formed in the silicon portion 4822. The active devices 4810 are probably compound semiconductor transistors such as high electron mobility transistors. The transmission lines 4812, 4814, 4818 are formed on the compound semiconductor material.

The phase shift elements 4816 in one embodiment are micro-electromechanical systems (MEMS). In our embodiments, the phase shift elements 4816 may comprise PIN diodes or other phase shift elements.

The control circuit 4802 is further formed in the silicon portion 4822. The control circuit 4802 generates control signals and bias signals which are provided to the phased-array channels 4804, 4806, 4808 on signal lines 4824. Bias and control of the active device 4810 is provided by the control circuit 4802 on the control and bias lines 4824.

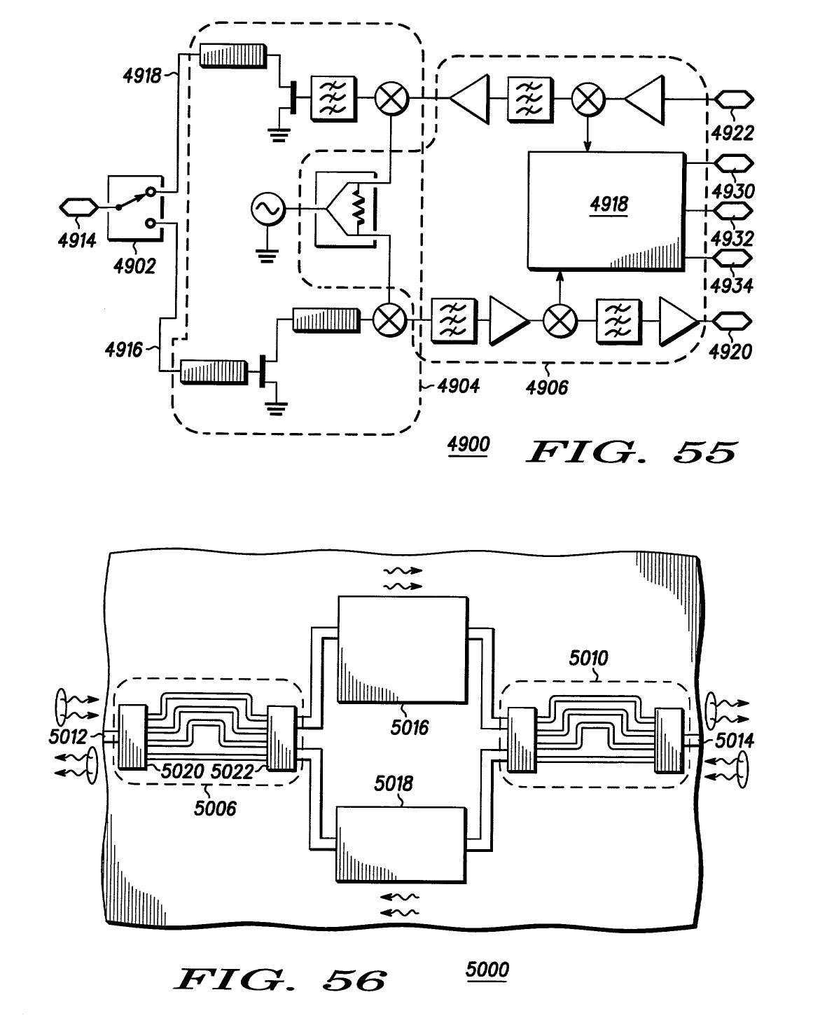

FIGS. 54, 55 show a semiconductor structure 4900 which may be operated as an integrated transceiver or radio. FIGS. 54, 55 show a schematic view of the semiconductor structure. FIGS. 54, 55 show a partial layout view of the semiconductor structure 4900.

The semiconductor structure 4900 includes a transmit/receive switch 4902, a transmit/receive module 4904 and radio frequency/intermediate frequency (RF/IF) circuitry 4906.

In the illustrated embodiment of FIGS. 54, 55, the semiconductor structure 4900 is constructed of compound semiconductor devices and silicon devices integrated in a common integrated circuit or semiconductor structure. The semiconductor structure 4900 includes a monocrystaline silicon substrate 4910, a buffer layer and a monocrystaline compound semiconductor layer. The buffer layer in the illustrated embodiment includes an amorphous oxide material overlying the monocrystaline silicon substrate 4910 and a monocrystaline perovskite oxide material overlying the amorphous oxide material. The monocrystaline compound semiconductor material 4912 overlies the monocrystaline perovskite oxide material. The semiconductor structure 4900 may be designed or manufactured in accordance with any of the embodiments herein.

The transmit/receive switch 4902 is coupled with an antenna terminal 4914. The transmit/receive switch 4902 in the illustrated embodiment is formed using a micro-electromechanical system (MEMS) switch. In other embodiments, the switch 4902 could be formed using a diode or field effect transistor. The transmit/receive switch 4902 has coupled by a transmission line 4916 to a transmit section of the transmit/receive module 4904. Similarly, the transmit/receive switch 4902 is coupled with a receive section of the transmit/receive module 4904 by a transmission line 4918.

The transmit/receive module 4904 includes a transmit section and a receive section. Further, the transmit/receive module 4904 includes an oscillator section which generates one or more carrier signals used for up conversion or down conversion of receive and transmit signals respectively. In the illustrated embodiment, the transmit/receive module 4904 and its constituent elements are fabricated in the monocrystaline compound semiconductor material 4912 of the semiconductor structure 4900. In alternative embodiments, some or all of the components of the transmit/receive module 4904 may be fabricated in a silicon portion of the semiconductor structure 4900.

The RF/IF section 4906 includes a RF to baseband section, a baseband to RF section and a control section 4918. The RF to baseband section is coupled with the receive circuit of the transmit/receive module 4904 and with a baseband output 4920. The baseband to RF section is coupled with a baseband input 4922 and the transmit section of the transmit/receive module 4904. The RF to baseband section receives radio frequency signals from the receive section and produces baseband signals at the baseband output 4920. Similarly, the baseband to RF section receives baseband signals at the baseband input 4922 and produces radio frequency signals for the transmit section of the transmit/receive module 4904. The baseband input 4922 and baseband output 4920 may be electrically coupled with other components of a radio or transceiver incorporating the semiconductor structure 4900. The other components may be on a separate integrated circuit or semiconductor structure or may be integrated with the same integrated circuit as the semiconductor structure illustrated in FIGS. 54, 55.

The control section 4918 provides control, bias, modulation, demodulation, error correction, encoding and other signal processing required by the transceiver formed by the semiconductor structure 4900. In the illustrated embodiment, the RF to baseband section, the baseband to RF section and the control section 4918 are commonly implemented in a silicon portion of the semiconductor structure 4900. The silicon portion may be the monocrystalline silicon substrate 4910 of the semiconductor structure 4900 or may be a silicon layer, such as epitaxial silicon, formed on the monocrystaline silicon substrate. The control section 4918 communicates control, bias and monitor signals at terminals 4930, 4932, 4934. One or more transmission lines 4936 interconnect the transmit/receive module 4904 and the RF/IF circuit 4906.

The semiconductor structure 4900 may be operated as an integrated transceiver or radio. The illustrated embodiment is a single frequency transceiver. Multiple discrete frequencies, such as is used in multi-band cellular telephones and other similar devices could be implemented with a design similar to that illustrated in FIG. 54, 55. Devices or circuit elements could be switched in or out as needed, for example under control of the control section 4918, to obtain the proper frequency of operation. The preferred embodiment of such devices would be on or in a silicon portion such as the silicon substrate and could include MEMS devices or other devices such as tunable discrete filters, varactor diodes, and so forth.

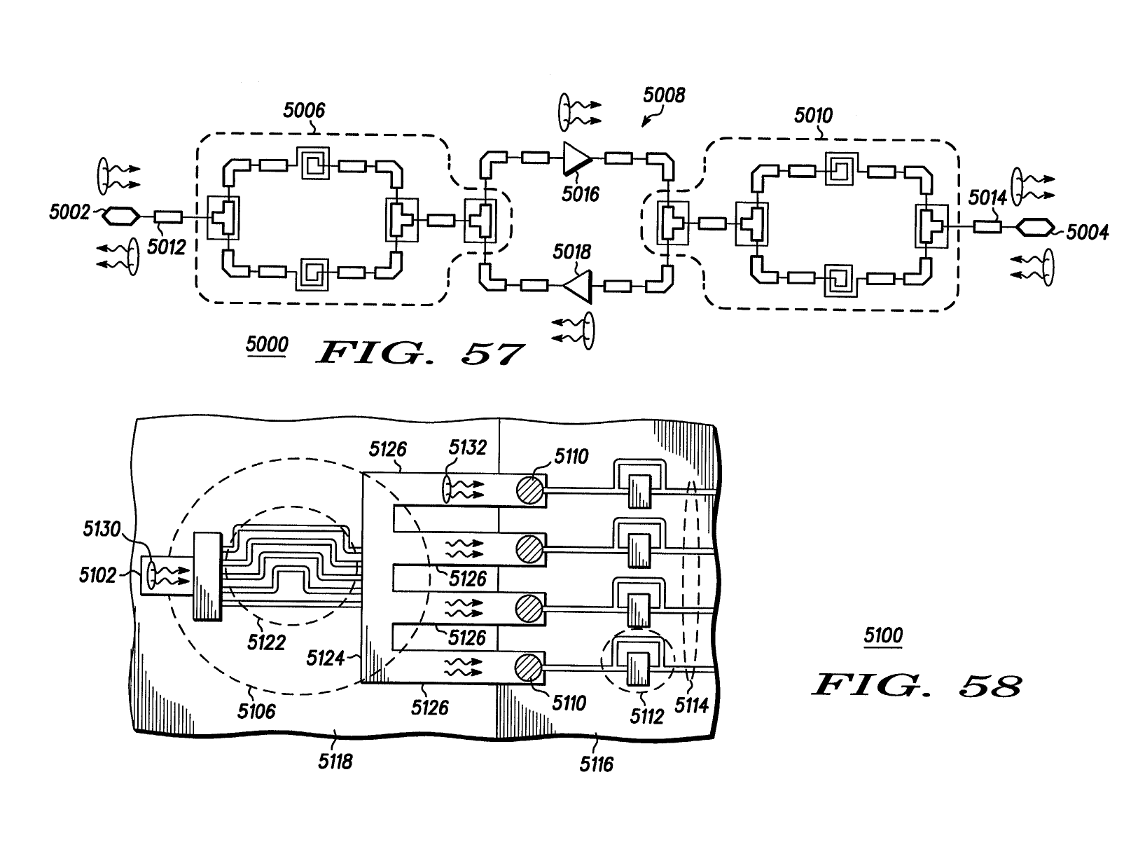

FIGS. 56, 57 illustrate a semiconductor structure 5000 operable as a bi-directional, bi-wavelength optical line amplifier. The amplifier simultaneously amplifies optical signals of two different wavelengths λ₁, and λ₂. The optical signals travel in opposite directions through the amplifier. The first signal of wavelength λ₁ is received at a terminal 5002 of the amplifier 5000 and, after amplification, provided at a terminal 5004. A second signal, of wavelength λ₂, is received at the terminal 5004, amplified and provided at the terminal 5002. These signals contain data that is modulated on the light wave carrier. Some typical values for the wavelengths which may be used in the semiconductor structure 5000 are 1300 nm for λ₁ and 1550 nm for λ₂. Such a system may provide data communication rates of 2.5 to 40 Gb/s, with 10 Gb/s being one particular embodiment.

The semiconductor structure 5000 includes a first Arrayed Waveguide Grating Multiplexer/demultiplexer (AWGM) 5006, an amplification section 5008 and a second AWGM 5010. The first AWGM 5006 is coupled to the terminal 5002 by an integrated optical waveguide 5012. Similarly, the second AWGM 5010 is coupled to the terminal 5004 by an integrated optical waveguide 5014.

The AWGM 5006, 5010 operates as a multiplexer and demultiplexer to separate and combine light signals in the semiconductor structure 5000. A single fiber that carries an integer number, in light signals of different wavelengths, λ₁,λ₂ . . . λₙ is fed to a star coupler. This device splits the incoming light signals into an integer number m, m≧n, identical signals. Each signal contains all of the wavelengths of the incoming signal. Each of the m signals is then fed into its own optical waveguide. The path length of each optical waveguide is designed so that there is a calculated length difference between the adjacent waveguides. Through constructive and destructive interference, the composite waveguides and output starcoupler function as a diffraction grating separating the signal into n separate signals. The number of waveguides m determines the spacing between wavelengths, that is the minimum λ₁-λ₂ and so on. Each of these signals is then fed into its own optical waveguide. Other methods could be substituted to achieve this function, such as using a Bragg grating, and so on.

The amplification section 5008 includes a first amplifier 5016 and a second amplifier 5018. The amplifiers 5016, 5018 may be implemented as semiconductor optical amplifiers, Raman amplifiers or Erbium Doped Fiber Amplifiers. The amplifiers preferably provide optical amplification with relatively high signal to noise ratio.

The semiconductor structure 5000 is preferably formed with both compound semiconductor and silicon devices and integrated in a common monolithic structure such as an integrated circuit. The semiconductor 5000 may be manufactured according to any of the embodiments described herein. In one embodiment, the semiconductor structure 5000 includes a monocrystaline silicon substrate, an amorphous oxide material overlying the monocrystaline silicon substrate, a monocrystaline perovskite oxide material overlying the amorphous oxide material and a monocrystaline compound semiconductor material overlying the monocrystaline perovskite oxide material.

In FIGS. 56, 57, it can be seen that in the illustrated embodiment the optical amplifiers 5016, 5018 are formed in a compound semiconductor portion of the semiconductor structure 5000. Further, in FIGS. 56, 57 it can further be seen that the AWGM 5006, 5010, including an input star coupler 5020, an output star coupler 5022 and optical waveguides 5024 are all formed in a silicon portion of the semiconductor structure 5000. The silicon portion compound semiconductor portion may be a portion of the monocrystaline silicon substrate, an overlying silicon layer such as expiation silicon, or a combination of the two. In alternative embodiments, the distribution of components among the compound semiconductor portion and the silicon portion may be varied to take advantage of particular operational or other advantages of these respective materials.

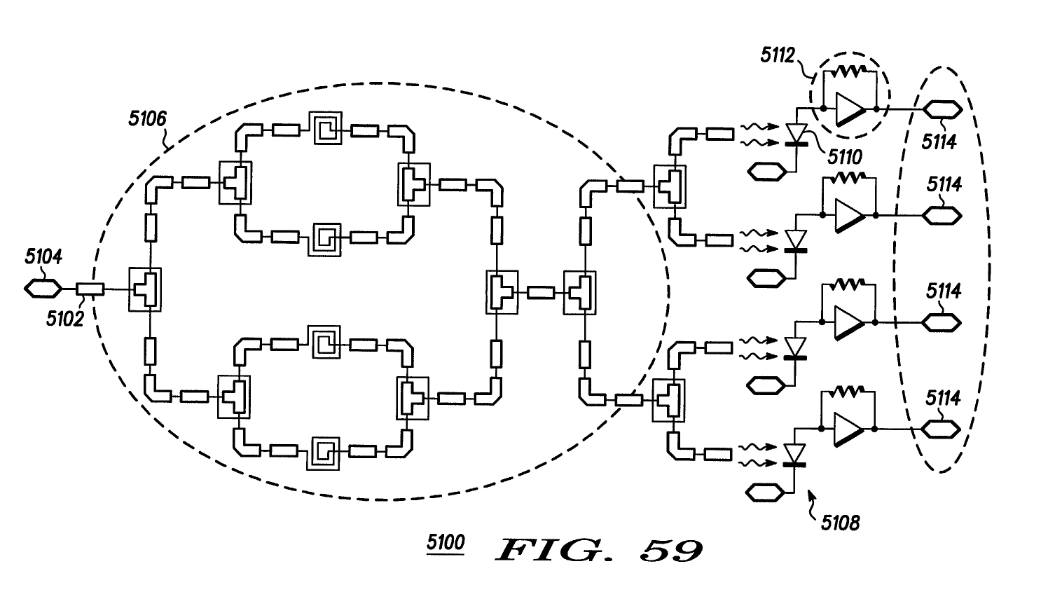

FIGS. 58, 59 illustrate a semiconductor structure 5100 which may be operated as a multiple channel transimpedance amplifier. The semiconductor structure 5100 includes an input optical waveguide 5102 coupled with an input 5104, an arrayed waveguide grating demultiplexer (AWGD) 5106 and a plurality of output channels 5108. Each output channel 5108 includes a photodiode 5110 and a transimpedance amplifier 5112 coupled to an output 5114.

FIGS. 58, 59 illustrate that the semiconductor structure 5100 is preferably formed from a combination of compound semiconductor devices and silicon devices, integrated in a common integrated circuit or semiconductor structure. The semiconductor structure 5100 may be manufactured in accordance with any of the embodiments described herein. In one embodiment, the semiconductor structure 5100 includes a monocrystalline silicon substrate 5116 and a buffer layer overlying the monocrystalline silicon substrate 5116. Also in one embodiment, the buffer layer includes an amorphous oxide material overlying the monocrystalline silicon substrate and a monocrystaline perovskite oxide material overlying the amorphous oxide materials. A monocrystaline compound semiconductor material 5118 overlies the monocrystaline perovskite oxide material.

As can be seen in FIGS. 58, 59, the AWGD 5106 includes an input star coupler 5120, input optical waveguide 5122, an output star coupler 5144 and integrated optical waveguides 5126. The AWDG 5106 operates to receive a composite optical signal 5130 and produce split optical signals 5132 corresponding to each of the constituent signals on the input composite optical signal 5130. Light in the optical waveguides 5126 impinges on the photodiodes 5110, producing electrical signals related to the split optical signal in the waveguide 5126. The transimpedance amplifier 5112 amplifies the signal produced by the photodiode 5110 and produces an output signal at the signal output 5114.

In accordance with the illustrated embodiment, the photodiodes 5110 and the transimpedance amplifiers 5112 are formed of silicon devices on a silicon portion of the semiconductor structure 5100. The silicon portion may include portions of the silicon substrate or a silicon layer, such as epitaxial silicon or epitaxial SiGe, formed on a portion of the silicon substrate 5116. Further, other devices such as the optical waveguides 5122, 5126 and star couplers 5120, 5124 are formed in a compound semiconductor portion of the semiconductor structure 5100.

The illustrated embodiment of FIGS. 58, 59 incorporates structure and function that can demultiplex light signals and send each of the discrete light signals having wave lengths λ₁,λ₂ . . . λₙ into separate channels. In this embodiment, n=4. However, in other embodiments, n may be any integer greater than 1 and is limited only by the area on the semiconductor structure 5100 that may be devoted to the device. The method of demultiplexing can be implemented using an arrayed waveguide grating multiplexor/demultiplexor (AWGM), a Bragg grating or other suitable device to achieve the separation of the combined light signals.

The separated like signals are routed down individual integrated optical waveguides 5126. The light signals activate the photodiodes 5110, which may be, for example, PIN photodiodes. The modulated light signal is converted into a modulated diode current. This current is fed to the transimpedance amplifiers 5112 for amplification. The output signals at the outputs 5114 may be further processed by other devices of the semiconductor structure 5100.

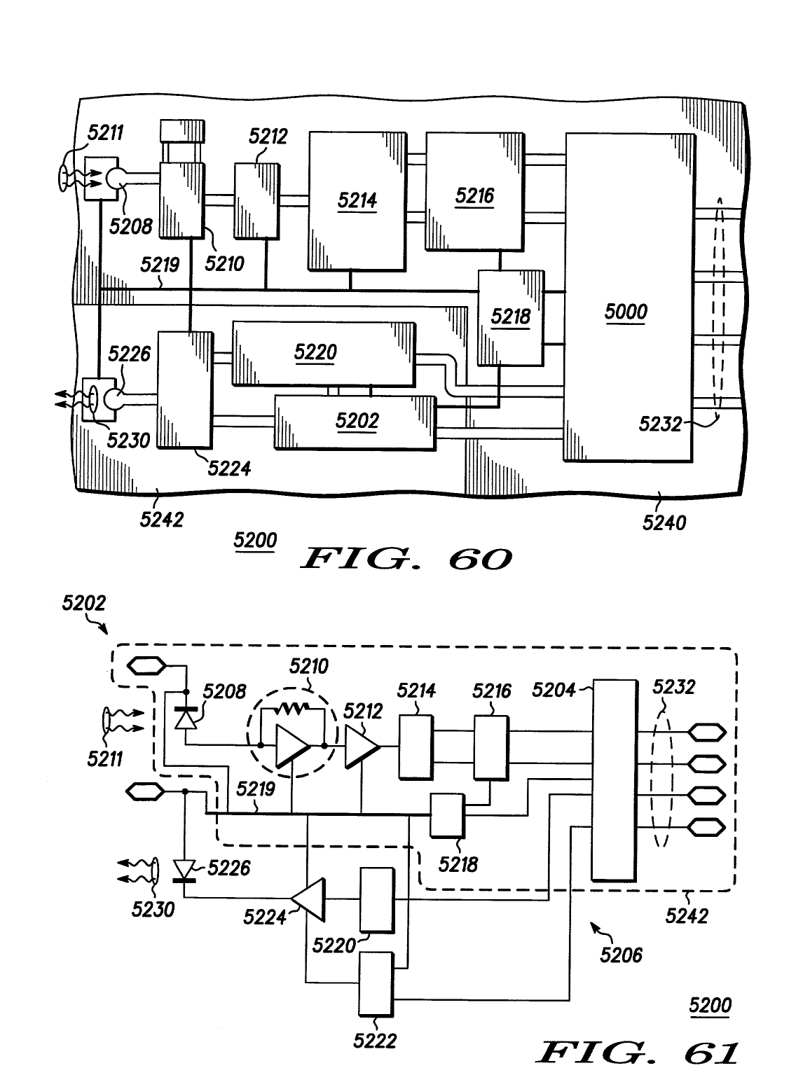

FIGS. 60, 61 illustrate a semiconductor structure 5200 which may be operated as an integrated optical transceiver. The semiconductor structure 5200 includes all of the necessary devices, circuits and functions required to implement a complete optical transceiver on a single semiconductor structure or integrated circuit. The optical transceiver 5200 includes an optical to RF chain or down converter 5202, a control circuit 5204 and a RF to optical chain or up converter 5206.

The down converter includes a photodiode 5208 which is responsive to an incoming optical signal 5211 which conveys data. The down converter 5202 further includes a transimpedance amplifier 5210, an amplifier 5212, a clock and data recovery circuit 5214 and a demultiplexor 5216. The incoming light signals 5211 activate the photodiode 5208, producing an input signal for the transimpedance amplifier 5210. The output signal from the transimpedance amplifier 5210 is provided to the amplifier 5212. The amplifier 5212 may be a limiting amplifier or automatic gain control amplifier.

The output signal from the amplifier 5212 is provided to the clock and data recovery circuit 5214. This circuit serves as the signal source for clocking and multiplexing and demultiplexing functions. Output signals from the clock and data recovery circuit 5214 are provided to the demultiplexer 5216 which is in communication with and under control of the control circuit 5204. The control circuit 5204 may be any suitable control circuit, such as a microprocessor, digital signal processor, or specialized logic device. The control circuit 5204 may include memory devices for storing data and instructions which operate the control circuit 5204.

The up converter 5206 includes a control circuit 5218, a multiplexer 5220, a clock synchronization circuit 5222, a laser driver 5224 and a laser 5226. The control circuit 5218 produces on chip control signals on a control bus 5219. The control bus 5219 may also be used for receiving control signals and control data at the control circuit 5218. The control circuit 5218 is in communication with the control circuit 5204.

The multiplexer 5220 and the clock synchronization circuit 5222 drive the laser driver 5224 with data for transmission from the transceiver 5200. The laser driver 5224 in turn provides the necessary voltage and current signals to drive the laser 5226. The laser 5226 may be a VCSEL, laser diode or any other suitable optical output device. The laser 5226 produces output optical signals 5230. The control circuit 5204 has data and control lines 5232 for control, input and output of data.

FIGS. 60, 61 further show a partial layout of the optical transceiver of the semiconductor structure 5200. FIGS. 60, 61 illustrate that the semiconductor structure 5200 includes compound semiconductor devices and silicon devices formed together on a common semiconductor structure or integrated circuit. The semiconductor structure may be formed according to any of the embodiments described herein. In one embodiment, the semiconductor structure 5200 includes a monocrystaline silicon substrate 5232, a buffer layer overlying the monocrystaline silicon substrate and a monocrystaline compound semiconductor material 5242. Further, in one embodiment, the buffer layer includes an amorphous oxide material overlying the monocrystaline silicon substrate and a monocrystaline perovskite oxide material overlying the amorphous oxide material. The monocrystaline compound semiconductor material 5242 overlies the monocrystaline perovskite oxide material.

In the embodiment of FIGS. 60, 61, the photodetecor diode 5208, the transimpedance amplifier 5210, the amplifier 5212, the clock and data recovery circuit 5214, the demultiplexor 5216 and the processor 5204 and the control circuit 5218 include at least some silicon devices formed in a silicon portion of the semiconductor structure 5200. The silicon portion includes the monocrystaline silicon substrate 5240 and silicon layers, such as epitaxial silicon or epitaxial SiGe which may be formed on the monocrystaline silicon substrate 5240. Further, the multiplexor 5220, the clock synchronization circuit 5222, the laser driver 5224 and the laser diode 5226 are all formed at least in part in the compound semiconductor portion of the semiconductor structure 5200. In other embodiments, the components of the semiconductor structure 5200 may be partitioned alternatively, so that components shown as being formed of silicon in FIGS. 60, 61 are formed of compound semiconductor material, or vise versa. Substitution and modification are well within the purview of those ordinarily skilled in the art, and may be based upon design goals for the semiconductor structure, particular device and process capabilities and other factors as well.

In the foregoing specification, the invention has been described with reference to specific embodiments. However, one of ordinary skill in the art appreciates that various modifications and changes can be made without departing from the scope of the present invention as set forth in the claims below. Accordingly, the specification and FIG.s are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor structure comprising:
a monocrystalline silicon substrate;
an amorphous oxide material overlying the monocrystalline silicon substrate on a first side of the semiconductor structure;
a monocrystalline perovskite oxide material overlying the amorphous oxide material;
a monocrystalline compound semiconductor material overlying the monocrystalline perovskite oxide material;
one or more silicon devices formed in the monocrystalline silicon substrate;
one or more compound semiconductor devices formed in the monocrystalline compound semiconductor material;
a metal layer interconnecting at least one compound semiconductor device and at least one silicon device on a surface of the first side of the semiconductor structure with reliable step coverage for the topography of the surface.

2. The semiconductor structure of claim 1 further comprising:
a metallic ground plane formed on a second side of the semiconductor structure.

3. The semiconductor structure of claim 2 wherein the metal layer forms a transmission line in association with the metallic ground plane.

4. The semiconductor structure of claim 1 further comprising
a metal via from the first side of the semiconductor structure to a second side of the semiconductor structure.

5. The semiconductor structure of claim 4 further comprising:
a metallic ground plane formed on the second side of the semiconductor structure, the metal via electrically contacting the metallic ground plane.

6. The semiconductor structure of claim 4 further comprising:
a second metal via from the first side of the semiconductor structure to the second side of the semiconductor structure; and
a second side metal layer formed on the second side of the semiconductor structure and including an interconnect portion electrically contacting both the metal via and the second metal via.

7. The semiconductor structure of claim 6 wherein the second side metal layer further comprises a ground plane portion.

8. The semiconductor structure of claim 7 further comprising:
second side insulation layer electrically insulating the interconnect portion and the ground plane portion of the second side metal layer.

9. The semiconductor structure of claim 1 further comprising:
a dielectric layer overlying the monocrystalline compound semiconductor material;
a monocrystalline semiconductor layer overlying the dielectric layer;
one or more semiconductor devices formed in the monocrystalline semiconductor layer; and
a metallic via extending through the dielectric layer.

10. The semiconductor structure of claim 9 wherein the metallic via forms an electrical connection between the metal layer and a semiconductor device formed in the monocrystalline semiconductor layer.

11. The semiconductor structure of claim 9 further comprising:
a second metal layer overlying the dielectric layer, the metallic via in electrical contact with a portion of the second metal layer.

12. The semiconductor structure of claim 11 wherein the metallic via forms an electrical connection between the metal layer and the second metal layer.

13. The semiconductor structure of claim 11 wherein the metallic via forms an electrical connection between a compound semiconductor device and the second metal layer.

14. The semiconductor structure of claim 9 further comprising:
ground plane metallization overlying the dielectric layer; and
a metallic via defined in the dielectric layer to electrically contact the ground plane metallization.

15. A semiconductor structure comprising:
a monocrystalline silicon substrate;
an amorphous oxide material overlying the monocrystalline silicon substrate on a first side of the semiconductor structure;
a monocrystalline perovskite oxide material overlying the amorphous oxide material;
a monocrystalline compound semiconductor material overlying the monocrystalline perovskite oxide material;
one or more compound semiconductor devices formed in the monocrystalline compound semiconductor material;
metallization on the first side of the semiconductor structure; and
a via extending through the monocrystalline compound semiconductor material, the monocrystalline perovskite oxide material and the amorphous oxide material to form an electric plane probe in the monocrystalline silicon substrate.

16. The semiconductor structure of claim 15 wherein the monocrystalline silicon substrate is doped to be conductive.

17. The semiconductor structure of claim 15 further comprising:
a metallic ground plane overlying the monocrystalline silicon substrate on a second side of the semiconductor structure.

18. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a compound semiconductor light emitting device; and
a compound semiconductor light detecting device conFIG.d to detect light emitted by the light emitting device, forming an optical interconnect of the semiconductor structure.

19. The semiconductor structure of claim 18 wherein the light emitting device comprises a light emitting diode.

20. The semiconductor structure of claim 18 wherein the light emitting device comprises a laser.

21. The semiconductor structure of claim 20 wherein the light emitting device comprises a vertical cavity surface emitting laser.

22. The semiconductor structure of claim 20 wherein the light emitting device and the light detecting device are coplanar in the monocrystalline compound semiconductor material.

23. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a compound semiconductor light emitting device formed in the monocrystalline compound semiconductor material; and
a silicon light detecting device formed in the monocrystalline silicon substrate and conFIG.d to detect light emitted by the compound semiconductor light emitting device, forming an optical interconnect of the semiconductor structure.

24. The semiconductor structure of claim 23 further comprising:
a light reflecting device positioned to reflect light from the compound semiconductor light emitting device to the silicon light detecting device.

25. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a compound semiconductor light emitting device formed in the monocrystalline compound semiconductor material;
a compound semiconductor light detecting device formed in the monocrystalline compound semiconductor material; and
an optical waveguide coupled with the compound semiconductor light emitting device and the compound semiconductor light detecting device, forming an optical interconnect.

26. The semiconductor structure of claim 25 further comprising:
a dielectric layer formed between the compound semiconductor light emitting device and the compound semiconductor light detecting device, the optical waveguide formed on the dielectric layer.

27. The semiconductor structure of claim 26 wherein the optical waveguide comprises:
a reflective first end proximate the compound semiconductor light emitting device; and
a reflective second end proximate the compound semiconductor light detecting device.

28. The semiconductor structure of claim 26 further comprising a silicon device formed in the monocrystalline silicon substrate.

29. The semiconductor structure of claim 28 wherein the silicon device comprises a modulator in electrical communication with the compound semiconductor light emitting device.

30. The semiconductor structure of claim 26 further comprising a compound semiconductor device formed in the monocrystalline compound semiconductor material.

31. The semiconductor structure of claim 28 wherein the compound semiconductor device comprises an amplifier in electrical communication with the compound semiconductor light detecting device.

32. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a bipolar transistor; and
a first transmission line electrically coupled with a base of the bipolar transistor; and
a second transmission line electrically coupled with a collector of the bipolar transistor.

33. The semiconductor structure of claim 32 wherein the bipolar transistor comprises a silicon bipolar junction transistor formed in the monocrystalline silicon substrate.

34. The semiconductor structure of claim 32 wherein the bipolar transistor comprises compound semiconductor heterojunction bipolar transistor formed in the monocrystalline compound semiconductor material.

35. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a compound semiconductor transistor formed in the monocrystalline compound semiconductor material;
a first transmission line feeding a gate of the compound semiconductor transistor; and
a second transmission line feed by a drain of the compound semiconductor transistor.

36. The semiconductor structure of claim 35 further comprising:
an oscillator; and
a mixer coupled with the second transmission line and the oscillator.

37. The semiconductor structure of claim 36 further comprising:
a filter coupled to the mixer; and
an amplification circuit coupled with the filter.

38. The semiconductor structure of claim 37 wherein the oscillator and the mixer are formed from compound semiconductor devices.

39. The semiconductor structure of claim 38 wherein the filter and the amplification circuit are formed at least in part from silicon devices.

40. The semiconductor structure of claim 35 further comprising a control circuit coupled with the compound semiconductor transistor and formed at least in part from silicon devices.

41. A semiconductor structure operable as an integrated down converter, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a compound semiconductor transistor conFIG.d to receive an input signal;
a compound semiconductor oscillator;
a compound semiconductor mixer having a first input coupled with the compound semiconductor transistor and a second input coupled with the a compound semiconductor oscillator and an output;
a filter having an input coupled to the output of the compound semiconductor mixer and an output;
an amplification circuit having an input coupled with the output of the filter; and
a control circuit for controlling operation as an integrated down converter.

42. The semiconductor structure of claim 41 further comprising:
a first transmission line coupled between an input of the integrated down converter and the compound semiconductor transistor; and
a second transmission line coupled between a drain of the compound semiconductor transistor and the compound semiconductor mixer.

43. The semiconductor structure of claim 41 wherein the control circuit comprises silicon devices integrated on the monocrystalline silicon substrate.

44. The semiconductor structure of claim 43 wherein the amplification circuit includes a control input coupled with the control circuit to receive a control signal.

45. The semiconductor structure of claim 41 wherein the compound semiconductor transistor is coupled with the control circuit to receive a bias signal.

46. The semiconductor structure of claim 45 wherein the control circuit comprises silicon devices formed on a silicon portion of the semiconductor structure.

47. A semiconductor structure operable as a transimpedance amplifier, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a photodiode coupled with an input of the transimpedance amplifier and formed on a compound semiconductor portion of the semiconductor structure;
first and second amplifiers formed at least in part on a silicon portion of the semiconductor structure, the first amplifier coupled with the photodiode and the second amplifier coupled with an output of the transimpedance amplifier; and
a feedback resistor coupled from the output to the first amplifier.

48. The semiconductor structure of claim 47 further comprising a transmission line coupled between the photodiode and the first amplifier.

49. The semiconductor structure of claim 47 further comprising a transmission line coupled between the second amplifier and the output.

50. A semiconductor structure operable as an integrated phase shifter, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a plurality of phased array channels, each phased array channel including
a compound semiconductor transistor conFIG.d to receive a channel
input signal, and
a phase shift element.

51. The integrated phase shifter of claim 50 wherein the phase shift element is formed on a silicon portion of the semiconductor structure.

52. The integrated phase shifter of claim 51 wherein the phase shift element is formed on the silicon substrate of the semiconductor structure.

53. The integrated phase shifter of claim 51 wherein the phase shift element is formed of epitaxial silicon formed on a part of the silicon substrate of the semiconductor structure.

54. The integrated phase shifter of claim 50 wherein the phase shift element comprises a micro-electromechanical system.

55. The integrated phase shifter of claim 50 wherein the phase shift element comprises a PIN diode.

56. The integrated phase shifter of claim 50 further comprising:
a control circuit coupled with each phased array channel plurality of phased array channels.

57. A semiconductor structure operable as an integrated transceiver, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a transmit/receive switch conFIG.d to be coupled with an antenna;
a transmit/receive module coupled with the transmit/receive switch; and
a radio frequency (RF) and intermediate frequency (IF) circuit coupled with the receive module.

58. The semiconductor structure of claim 57 wherein the transmit/receive switch comprises a micro-electromechanical system.

59. The semiconductor structure of claim 57 further comprising a control circuit formed on a silicon portion of the semiconductor structure.

60. The semiconductor structure of claim 59 wherein the transmit/receive module comprises at least in part compound semiconductor devices formed in the monocrystalline compound semiconductor material.

61. A semiconductor structure operable as an optical line amplifier, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an input optical waveguide;
an input optical waveguide;
a first multiplexer/demultiplexer coupled with the input optical waveguide;
a second multiplexer/demultiplexer coupled with the output optical waveguide; and
optical amplifiers bi-directionally coupled between the first multiplexer/demultiplexer and the second multiplexer/demultiplexer.

62. The semiconductor structure of claim 61 wherein the optical amplifiers comprise semiconductor optical amplifiers.

63. The semiconductor structure of claim 61 wherein the optical amplifiers comprise Raman amplifiers.

64. The semiconductor structure of claim 61 wherein the optical amplifiers comprise Erbium doped fiber amplifiers.

65. The semiconductor structure of claim 61 wherein the first multiplexer/demultiplexer and the second multiplexer/demultiplexer each comprise an arrayed waveguide grating multiplexer/demultiplexers.

66. A semiconductor structure operable as a transimpedance amplifier, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an integrated optical waveguide conFIG.d to receive a composite optical signal including a plurality of individual optical signals;
an optical demultiplexer coupled with the integrated optical waveguide to separate the individual optical signals;
a plurality of photodetectors conFIG.d to convert the individual optical signals to individual electrical signals; and
an amplification circuit coupled with the plurality of photodetectors.

67. The semiconductor structure of claim 66 wherein the optical demultiplexer comprises an arrayed waveguide grating demultiplexer.

68. The semiconductor structure of claim 66 wherein the optical demultiplexer is formed at least in part of compound semiconductor devices on the monocrystalline compound semiconductor material.

69. The semiconductor structure of claim 68 wherein the amplifier circuit is formed at least in part of silicon devices of a silicon portion of the semiconductor structure.

70. The semiconductor structure of claim 68 wherein the amplifier circuit comprises a plurality of amplifiers, each amplifier operative to amplify a respective individual electrical signal.

71. The semiconductor structure of claim 68 wherein the photodiode is a silicon diode formed in a silicon portion of the semiconductor structure.

72. A semiconductor structure operable as an optical transceiver, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an optical to electrical converter circuit;
an electrical to optical converter circuit; and
a controller coupled with the optical to electrical converter circuit and the electrical to optical converter circuit.

73. The semiconductor structure of claim 72 wherein the optical to electrical converter circuit comprises:
a photodetector;
an amplification circuit coupled with the photodetector;
a clock and data recovery circuit coupled with the amplification circuit; and
a demultiplexer coupled with the clock and data recovery circuit.

74. The semiconductor structure of claim 72 wherein the electrical to optical converter circuit comprises:
a multiplexer;
a clock synchronization circuit coupled with the multiplexer;
a laser driver coupled with the clock synchronization circuit and the multiplexer; and
a laser diode coupled with the laser driver.

75. The semiconductor structure of claim 74 wherein the amplification circuit comprises:
a transimpedance amplifier; and
a limiting amplifier coupled in series with the transimpedance amplifier.
